(19) United States
(12) Patent Application Publication
(10) Pub. No.: US 2026/0026405 A1
(43) Pub. Date: Jan. 22, 2026

(54) SEMICONDUCTOR DIE, AND THREE-DIMENSIONAL STACKED DEVICE

(71) Applicant: Socionext Inc., Kanagawa (JP)

(72) Inventor: Shinichi MARUI, Yokohama (JP)

(21) Appl. No.: 19/251,281

(22) Filed: Jun. 26, 2025

(30) Foreign Application Priority Data
Jul. 16, 2024 (WO) PCT/JP2024/025471
Feb. 7, 2025 (JP) 2025-019539

(51) Int. Cl. H01L 23/00; H01L 25/065

(52) U.S. Cl. CPC H01L 24/06; H01L 25/0657; H01L 2224/06177; H01L 2224/06181; H01L 2225/06513; H01L 2225/06517; H01L 2225/06562

(57) ABSTRACT

A semiconductor die includes: a main body including a top surface and a bottom surface; a plurality of first bonding pads disposed on the top surface; and a plurality of second bonding pads disposed on the bottom surface. When viewed in a direction perpendicular to the top surface or the bottom surface, the plurality of first bonding pads are disposed at positions that match positions to which the plurality of second bonding pads are shifted in a plane of the bottom surface while maintaining a positional relationship between the plurality of second bonding pads. The main body includes a first inter-die interface circuit and a second inter-die interface circuit. The plurality of first bonding pads are connected to the first inter-die interface circuit, and the plurality of second bonding pads are connected to the second inter-die interface circuit.

### CROSS REFERENCE TO RELATED APPLICATIONS

The present application is based on and claims priority of PCT International Patent Application No. PCT/JP2024/025471 filed on Jul. 16, 2024, and priority of Japanese Patent Application No. 2025-019539 filed on Feb. 7, 2025. The entire disclosures of the above-identified applications, including the specifications, drawings and claims are incorporated herein by reference in their entirety.

### FIELD

The present disclosure relates to a semiconductor die, etc.

### BACKGROUND

In recent years, a system on a chip (SoC) equipped with various functions such as a central processing unit (CPU), a graphics processing unit (GPU), or memory on a single semiconductor chip has been widely used. As an SoC manufacturing technique, a technique of manufacturing a CPU, a GPU, or memory as individual parts (i.e., semiconductor die) from different wafers, etc., and then electrically connecting these parts on a package substrate is known. As a method of electrically connecting a plurality of semiconductor dies, there are a 2.5 dimensional stacking method and a three-dimensional stacking method disclosed in Patent Literature (PTL) 1, for example.

In PTL 1, cores having the same arithmetic functions are arranged in array on a semiconductor die, and semiconductor dies each being the semiconductor die are stacked in a three-dimensional stacking method so as to meet the performance requirements of GPUs for AI operations which require a huge amount of arithmetic capacity.

In addition, an SoC in which a plurality of semiconductor dies having the same configuration are stacked using a three-dimensional stacking method is disclosed in PTL 2. In PTL 2, the stacked semiconductor dies are surrounded (i.e., packaged) by a member with high thermal conductivity so as to facilitate dissipating heat generated in each of the semiconductor dies by the SoC operation.

Non Patent Literature (NPL) 1 discloses the results of a simulation carried out on the assumption of stacking two semiconductor dies in which the arrangement of the respective circuits are in a mirror image relationship to each other as semiconductor dies having the same function, in order to shift the location where heat is generated between the semiconductor dies positioned above and below.

### CITATION LIST

### Patent Literature

PTL 1: US Patent Application Publication No. 2024/0128216
PTL 2: US Patent Application Publication No. 2023/0253369

### Non Patent Literature

NPL 1: R. Mathur et al., “Thermal Analysis of a 3D stacked High-Performance Commercial Microprocessor using Face-to-Face Wafer Bonding Technology,” 2020 IEEE 70th Electronic Components and Technology Conference (ECTC), Orlando, FL, USA, 2020, pp. 541-547, doi: 10.1109/ECTC32862.2020.00091.

### SUMMARY

### Technical Problem

However, in the SoC described in PTL 2, as pointed out in NPL 1, stacking multiple semiconductor dies having the same configuration means that the locations where heat is generated in each semiconductor die are same in the stacking direction, leading to an increase in density of heat sources inside the SoC. In other words, with the SoC described in PTL 2, there are instances where heat is trapped inside the SoC, leading to insufficient heat dissipation.

In the SoC described in NPL 1, it is essential to manufacture two types of semiconductor dies which are same in function and different in layouts. Manufacturing two types of semiconductor dies which are same in function and different in configurations, for example, causes problems such as longer time required to design the semiconductor die to be used in the SoC than before, or higher cost than before.

The present disclosure is to solve the above-described problems and to provide a semiconductor die, etc. capable of more efficiently dissipating heat generated inside an SoC that includes a plurality of semiconductor dies which are stacked and same in configuration.

### Solution to Problem

In order to achieve the above-described object, one aspect of a semiconductor die according to the present disclosure is a semiconductor die that is used in a three-dimensional stacked device including a plurality of semiconductor dies which are same in configuration and stacked on one another, the plurality of semiconductor dies each being the semiconductor die. The semiconductor die includes: a main body including a top surface and a bottom surface; a plurality of first bonding pads disposed on the top surface; and a plurality of second bonding pads disposed on the bottom surface. In the semiconductor die, the top surface is one of principal surfaces of the main body, the bottom surface is a surface opposing the top surface, when viewed in a direction perpendicular to the top surface or the bottom surface, the plurality of first bonding pads are disposed at positions that match positions to which the plurality of second bonding pads are shifted in a plane of the bottom surface while maintaining a positional relationship between the plurality of second bonding pads, the main body includes a first inter-die interface circuit and a second inter-die interface circuit which are disposed between the top surface and the bottom surface, the second inter-die interface circuit being different from the first inter-die interface circuit, the plurality of first bonding pads are connected to the first inter-die interface circuit, and the plurality of second bonding pads are connected to the second inter-die interface circuit.

In order to achieve the above-described object, one aspect of a three-dimensional stacked device according to the present disclosure is a three-dimensional stacked device having a configuration in which the plurality of semiconductor dies according to the present disclosure are stacked. In the three-dimensional stacked device, the plurality of semiconductor dies include a first semiconductor die and a second semiconductor die, and when viewed in the direction perpendicular to the top surface or the bottom surface, the second semiconductor die is stacked above the first semiconductor die, with positions of the plurality of second bonding pads included in the second semiconductor die matching positions of the plurality of first bonding pads included in the first semiconductor die.

In order to achieve the above-described object, one aspect of a three-dimensional stacked device according to the present disclosure is a three-dimensional stacked device having a configuration in which the plurality of semiconductor dies according to the present disclosure are stacked. In the three-dimensional stacked device, the plurality of semiconductor dies include a first semiconductor die and a second semiconductor die, and the second semiconductor die is stacked above the first semiconductor die: with positions of the plurality of second bonding pads included in the second semiconductor die matching positions of the plurality of first bonding pads included in the first semiconductor die, when viewed in the direction perpendicular to the top surface or the bottom surface; or with the positions of the plurality of second bonding pads included in the second semiconductor die matching positions of the plurality of third bonding pads included in the first semiconductor die, when viewed in the direction perpendicular to the top surface or the bottom surface.

In order to achieve the above-described object, one aspect of a three-dimensional stacked device according to the present disclosure is a three-dimensional stacked device having a configuration in which the plurality of semiconductor dies according to the present disclosure are stacked. In the three-dimensional stacked device, the plurality of semiconductor dies include a first semiconductor die and a second semiconductor die, and the second semiconductor die is stacked above the first semiconductor die: with positions of the plurality of second bonding pads included in the second semiconductor die matching positions of the plurality of first bonding pads included in the first semiconductor die, when viewed in the direction perpendicular to the top surface or the bottom surface; or with positions of the plurality of fourth bonding pads included in the second semiconductor die matching the positions of the plurality of first bonding pads included in the first semiconductor die, when viewed in the direction perpendicular to the top surface or the bottom surface.

### Advantageous Effects

The present disclosure provides a semiconductor die, etc. capable of more efficiently dissipating heat generated inside an SoC that includes a plurality of semiconductor dies which are stacked and same in configuration.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic diagram illustrating an example of the configuration of a semiconductor die according to Embodiment 1.

FIG. 2A is a schematic diagram illustrating a configuration of a three-dimensional stacked device when viewed in a direction parallel to the Y direction.

FIG. 2B is a schematic diagram illustrating the configuration of the three-dimensional stacked device when viewed in a direction parallel to the Z direction.

FIG. 3A is a schematic diagram illustrating the configuration of the three-dimensional stacked device when viewed in a direction parallel to the Y direction.

FIG. 3B is a schematic diagram illustrating the configuration of the three-dimensional stacked device when viewed in a direction parallel to the Z direction.

FIG. 4 is a schematic diagram illustrating an example of an electrical connection relation of the three-dimensional stacked device according to Embodiment 1.

FIG. 5A is a schematic diagram illustrating a first connection pattern when three semiconductor dies each include a plurality of first bonding pads, a plurality of second bonding pads, and a plurality of third bonding pads.

FIG. 5B is a schematic diagram illustrating a second connection pattern when three semiconductor dies each include the plurality of first bonding pads, the plurality of second bonding pads, and the plurality of third bonding pads.

FIG. 6A is a schematic diagram illustrating a first connection pattern when three semiconductor dies each include the plurality of first bonding pads, the plurality of second bonding pads, and a plurality of fourth bonding pads.

FIG. 6B is a schematic diagram illustrating a second connection pattern when three semiconductor dies each include the plurality of first bonding pads, the plurality of second bonding pads, and the plurality of fourth bonding pads.

FIG. 7A is a schematic diagram illustrating the configuration of the three-dimensional stacked device when viewed in a direction parallel to the Y direction.

FIG. 7B is a schematic diagram illustrating the configuration of the three-dimensional stacked device when viewed in a direction parallel to the Z direction.

FIG. 8 is a schematic diagram illustrating an example of a configuration of a semiconductor die according to Embodiment 2.

FIG. 9A is a schematic diagram illustrating the configuration of a three-dimensional stacked device when viewed in a direction parallel to the Y direction.

FIG. 9B is a schematic diagram illustrating the configuration of the three-dimensional stacked device when viewed in a direction parallel to the Z direction.

FIG. 10A is a schematic diagram illustrating the configuration of a three-dimensional stacked device when viewed in a direction parallel to the Y direction.

FIG. 10B is a schematic diagram illustrating the configuration of the three-dimensional stacked device when viewed in a direction parallel to the Z direction.

FIG. 11 is a schematic diagram illustrating an electrical connection relation of the three-dimensional stacked device illustrated in FIG. 9A and FIG. 9B.

FIG. 12A is a schematic diagram illustrating the configuration of a three-dimensional stacked device when viewed in a direction parallel to the Y direction.

FIG. 12B is a schematic diagram illustrating the configuration of the three-dimensional stacked device when viewed in a direction parallel to the Z direction.

FIG. 13 is a schematic diagram illustrating how bonding pads in one set are directly and electrically connected to each other inside a semiconductor die.

FIG. 14 is a schematic diagram illustrating how bonding pads in one set are connected to each other without direct electrical connection inside a semiconductor die.

FIG. 15A is a schematic diagram illustrating the case where a main body of the semiconductor die includes a first logic circuit inside.

FIG. 15B is a schematic diagram illustrating the case where the main body of the semiconductor die includes a second logic circuit inside.

FIG. 15C is a schematic diagram illustrating the case where the main body of the semiconductor die includes a first logic circuit and a second logic circuit inside.

FIG. 15D is a schematic diagram illustrating the case where signals are transmitted in two directions, from a top surface and from a bottom surface.

FIG. 16A is a schematic diagram illustrating the case where the main body of the semiconductor die includes two interface circuits inside.

FIG. 16B is a schematic diagram illustrating the case where the two interface circuits that the main body of the semiconductor die includes inside are electrically connected to each other.

### DESCRIPTION OF EMBODIMENTS

Hereinafter, embodiments of the present disclosure will be described with reference to the drawings. It should be noted that each of the embodiments described below shows a specific example of the present disclosure. As such, the numerical values, shapes, materials, structural components, the arrangement and connection of the structural components, processes (steps), the processing order of the processes, and so on, shown in the following embodiments are mere examples, and therefore do not limit the present invention. Furthermore, among the structural components in the following embodiments, components not recited in the independent claims which indicate the broadest concepts of the present disclosure are described as arbitrary structural components.

It should be noted that the respective figures are schematic diagrams and are not necessarily precise illustrations. Therefore, the scale sizes and the like are not necessarily exactly represented in each of the diagrams. Furthermore, in the respective figures, substantially identical components are assigned the same reference signs, and overlapping description is omitted or simplified. In the Specification, the terms “above” and “below” do not necessarily indicate an upper direction (vertically upward) and a lower direction (vertically downward) in absolute space recognition.

In addition, in this Specification, terms indicating the relationships between elements, such as perpendicular or parallel, and terms indicating the shapes of elements, such as quadrilateral, as well as value ranges do not have the meanings in the strict sense only, but also represent essentially equivalent meanings and value ranges, and include, for example, deviations of about a few percent.

In addition, in the respective figures, the direction in which the semiconductor dies are stacked is the Z direction, and the two directions included in the plane perpendicular to the Z direction and orthogonal to each other are the X direction and the Y direction.

### Embodiment 1

### [Semiconductor Die]

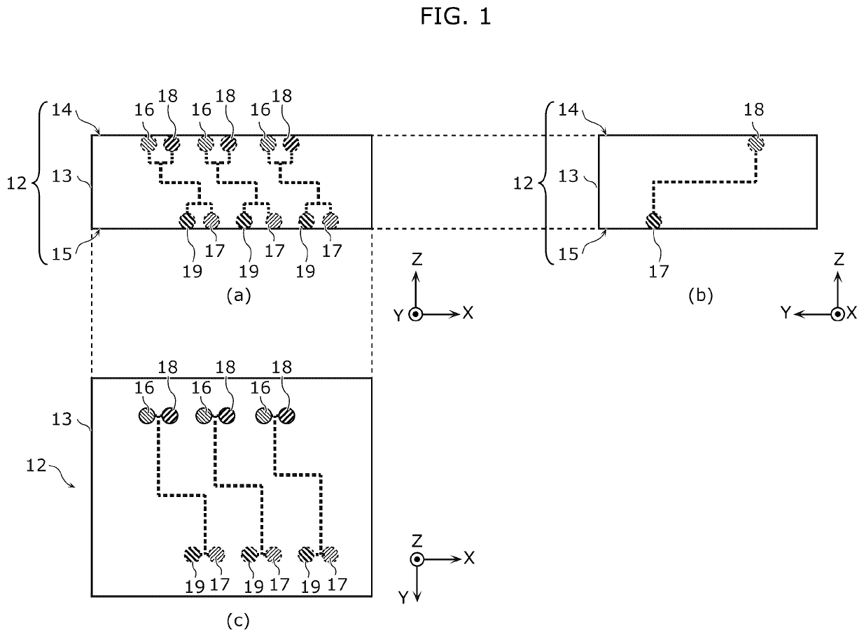

FIG. 1 is a schematic diagram illustrating an example of a configuration of semiconductor die 12 according to Embodiment 1. It should be noted that a plurality of first bonding pads 16, a plurality of second bonding pads 17, a plurality of third bonding pads 18, and a plurality of fourth bonding pads 19 illustrated in FIG. 1 are hatched for emphasis in explanation, and are not for indicating a cross-section. The same applies to the diagrams described below. FIG. 1 is also a diagram illustrating the inside of semiconductor die 12 for explaining the configuration of semiconductor die 12. In addition, (a) of FIG. 1 is a schematic diagram illustrating the configuration of semiconductor die 12 viewed in a direction parallel to the Y direction. It should be noted that the lines connecting between the bonding pads illustrated in (a) of FIG. 1 are lines schematically illustrating electrical connections and are not lines indicating accurate wiring paths. The same applies to the diagrams described below. In addition, (b) of FIG. 1 is a diagram schematically illustrating the configuration of semiconductor die 12 viewed in a direction parallel to the X direction. In addition, (c) of FIG. 1 is a schematic diagram illustrating the configuration of semiconductor die 12 viewed in a direction parallel to the Z direction.

As illustrated in FIG. 1, semiconductor die 12 is a semiconductor chip having a rectangular parallelepiped configuration, such as a CPU, a GPU, memory, or the like. Semiconductor die 12 is used, for example, for a three-dimensional stacked device including a plurality of semiconductor dies 12 which are same in configuration and stacked on one another. It should be noted that the shape of semiconductor die 12 may be other than a rectangular parallelepiped such as a polygonal column as long as the shape allows stacking the plurality of semiconductor dies 12.

Semiconductor die 12 includes main body 13, a plurality of first bonding pads 16, a plurality of second bonding pads 17, a plurality of third bonding pads 18, and a plurality of fourth bonding pads 19.

Main body 13 is, for example, a device including a semiconductor, and includes inside an element such as a transistor and a line. Main body 13 includes top surface 14 and bottom surface 15.

Top surface 14 is one of the principal surfaces included in main body 13, and one of the planes perpendicular to the Z direction.

Bottom surface 15 is one of the principal surfaces included in main body 13, and one of the planes perpendicular to the Z direction. Bottom surface 15 opposes top surface 14.

The plurality of first bonding pads 16, the plurality of second bonding pads 17, the plurality of third bonding pads 18, and the plurality of fourth bonding pads 19 are pads for use in electrically connecting to a different semiconductor die 12 or an electronic component.

As illustrated in (a) of FIG. 1, the plurality of first bonding pads 16 and the plurality of third bonding pads 18 are disposed on top surface 14. The plurality of second bonding pads 17 and the plurality of fourth bonding pads 19 are disposed on bottom surface 15. It should be noted that, although the schematic diagram illustrated in (a) of FIG. 1 shows an example in which semiconductor die 12 includes three first bonding pads 16, it is sufficient if at least two first bonding pads 16 are included in semiconductor die 12. The same is true for the plurality of second bonding pads 17, the plurality of third bonding pads 18, and the plurality of fourth bonding pads 19 included in semiconductor die 12. In addition, it is sufficient if semiconductor die 12 includes at least the plurality of first bonding pads 16 and the plurality of second bonding pads 17. In other words, semiconductor die 12 may include none of the plurality of third bonding pads 18 and the plurality of fourth bonding pads 19, or may include either the plurality of third bonding pads 18 or the plurality of fourth bonding pads 19.

The plurality of first bonding pads 16 and the plurality of third bonding pads 18 are arranged such that the ratio of the total number of pads is 1:1, but are not limited to this. For example, the plurality of first bonding pads 16 and the plurality of third bonding pads 18 may be arranged such that the ratio of the total number of pads is 2:1. The same is true for the arrangement relationship between the plurality of second bonding pads 17 and the plurality of fourth bonding pads 19.

Among the plurality of bonding pads included in semiconductor die 12, first bonding pad 16, second bonding pad 17, third bonding pad 18, and fourth bonding pad 19, which are bonding pads in one set, are electrically connected to one another via lines. More specifically, first bonding pad 16 and third bonding pad 18 are electrically connected to each other, second bonding pad 17 and fourth bonding pad 19 are electrically connected to each other, and first bonding pad 16 and third bonding pad 18 are electrically connected to second bonding pad 17 and fourth bonding pad 19.

In addition, the line connecting first bonding pad 16 and third bonding pad 18 which are bonding pads in one set may be provided inside semiconductor die 12, or may be provided on the top surface. In addition, the line connecting second bonding pad 17 and fourth bonding pad 19 which are bonding pads in one set may be provided inside semiconductor die 12, or may be provided on the bottom surface.

In addition, the plurality of first bonding pads 16 need not necessarily be electrically connected to one another. The same is true for the connection relation between the plurality of second bonding pads 17, the connection relation between the plurality of third bonding pads 18, and the connection relation between the plurality of fourth bonding pads 19.

As illustrated in (a), (b), and (c) of FIG. 1, the plurality of first bonding pads 16, the plurality of second bonding pads 17, the plurality of third bonding pads 18, and the plurality of fourth bonding pads 19 are respectively aligned in the X direction. For example, the plurality of first bonding pads 16, the plurality of second bonding pads 17, the plurality of third bonding pads 18, and the plurality of fourth bonding pads 19 may be aligned respectively in the Y direction, or they respectively need not be aligned when viewed in any of the directions on X-Y plane. In addition, when viewed in the direction parallel to the X direction, the plurality of first bonding pads 16 and the plurality of third bonding pads 18 need not necessarily be disposed at positions where they overlap each other. Likewise, when viewed in the direction parallel to the X direction, the plurality of second bonding pads 17 and the plurality of fourth bonding pads 19 need not necessarily be disposed at positions where they overlap each other. Likewise, when viewed in the direction parallel to the X direction, the plurality of first bonding pads 16, the plurality of second bonding pads 17, the plurality of third bonding pads 18, and the plurality of fourth bonding pads 19 need not necessarily be disposed on the same straight line parallel to the Z direction.

In addition, when viewed in the direction parallel to the Z direction, the plurality of first bonding pads 16 are disposed at positions where the plurality of first bonding pads 16 do not overlap the plurality of second bonding pads 17 or the plurality of fourth bonding pads 19. When viewed in the direction perpendicular to top surface 14 or bottom surface 15, the positions of the plurality of first bonding pads 16 match the positions to which the plurality of second bonding pads 17 are shifted in the plane of bottom surface 15 while maintaining the positional relationship between the plurality of second bonding pads 17. In addition, when viewed in the direction perpendicular to top surface 14 or bottom surface 15, the positions of the plurality of first bonding pads 16 match the positions to which the plurality of fourth bonding pads 19 are shifted in the plane of bottom surface 15 while maintaining the positional relationship between the plurality of fourth bonding pads 19. More specifically, as illustrated in (c) of FIG. 1, when viewed in the direction parallel to the Z direction, the positions of the plurality of second bonding pads 17 and the plurality of fourth bonding pads 19, when shifted parallel in the X-Y plane, match the positions of the plurality of first bonding pads 16.

The positions of the plurality of third bonding pads 18, when viewed in the direction perpendicular to top surface 14 or bottom surface 15, match the positions to which the plurality of second bonding pads 17 are shifted in the plane of bottom surface 15 while maintaining the positional relationship between the plurality of second bonding pads 17. In addition, when viewed in the direction perpendicular to top surface 14 or bottom surface 15, the positions of the plurality of third bonding pads 18 match the positions to which the plurality of fourth bonding pads 19 are shifted in the plane of bottom surface 15 while maintaining the positional relationship between the plurality of fourth bonding pads 19. More specifically, as illustrated in (c) of FIG. 1, when viewed in a direction parallel to the Z direction, the positions of the plurality of second bonding pads 17 and the plurality of fourth bonding pads 19, when shifted parallel in the X-Y plane, match the positions of the plurality of third bonding pads 18.

### [Three-Dimensional Stacked Device]

The following describes the three-dimensional stacked device having a configuration in which the plurality of semiconductor dies 12 described above are stacked. In addition, although the three-dimensional stacked device in which three semiconductor dies 12 are stacked will be exemplified in the following description, any three-dimensional stacked devices are included in the present disclosure as long as the three-dimensional stacked device includes at least two semiconductor dies 12 stacked therein. In addition, in the following description, an additional character of “A”, “B”, or “C” is added to numerical references as in semiconductor die 12A, 12B, or 12C. Semiconductor dies 12A, 12B, and 12C are each semiconductor die 12 having the same configuration, but are differentiated for making the description easier to understand. Therefore, when it is not necessary to specifically differentiate them, they may be simply referred to as “semiconductor die 12”. Furthermore, although an additional character of “A”, “B”, or “C” is added to numerical references of the structural components included in semiconductor dies 12A, 12B, and 12C for the same reason, when it is not necessary to specifically differentiate them, they may be described without the additional character of “A”, “B”, or “C”.

In addition, in the following description, the position of main heat source that generates heat in semiconductor die 12 when the three-dimensional stacked device is performing an operation is indicated as heat 20. Heat 20 indicated in semiconductor die 12 is a mark indicating the location where the amount of heat generated inside semiconductor die 12 is particularly large. Accordingly, when the three-dimensional stacked device in which a plurality of semiconductor dies 12 having the same configuration are stacked is performing an operation, the positions of the heat sources of the respective semiconductor dies 12 are same when the individual semiconductor dies 12 are compared. Furthermore, although an additional character of “A”, “B”, or “C” is also added to numerical references of heat 20 indicated in semiconductor dies 12A, 12B, and 12C for making the description easier to understand, when it is not necessary to specifically differentiate them, they may be described without the additional character of “A”, “B”, or “C”.

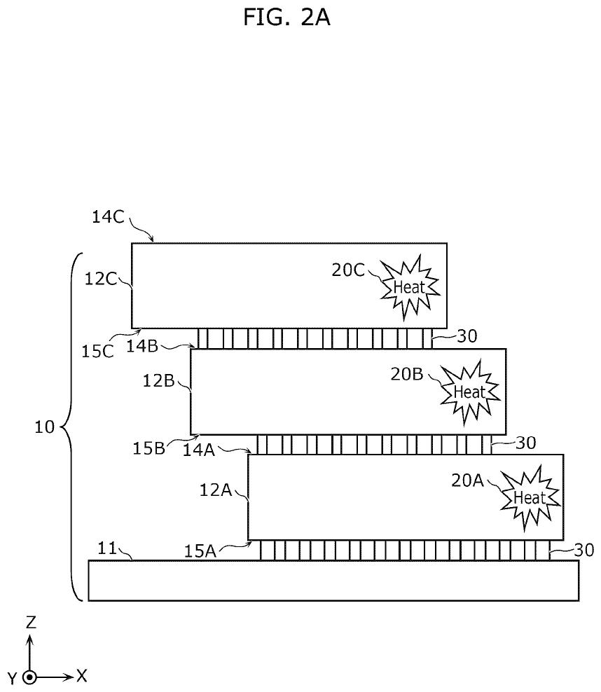

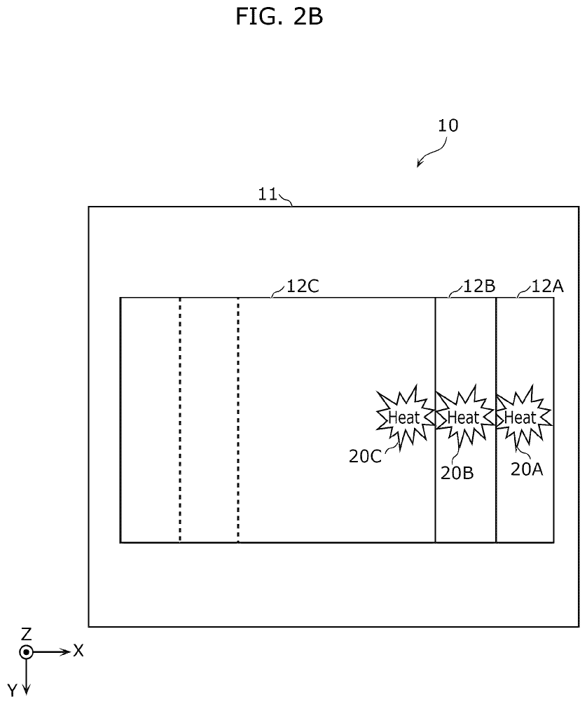

An example of a configuration of three-dimensional stacked device 10 according to Embodiment 1 will be described with reference to FIG. 2A and FIG. 2B. FIG. 2A is a schematic diagram illustrating the configuration of three-dimensional stacked device 10 viewed in a direction parallel to the Y direction. FIG. 2B is a schematic diagram illustrating the configuration of three-dimensional stacked device 10 viewed in a direction parallel to the Z direction. It should be noted that FIG. 2B is a schematic diagram illustrating three-dimensional stacked device 10 illustrated in FIG. 2A viewed in a direction parallel to the Z direction.

As illustrated in FIG. 2A, three-dimensional stacked device 10 includes substrate 11, three semiconductor dies 12, and bump 30. In three-dimensional stacked device 10, substrate 11, semiconductor die 12A, semiconductor die 12B, and semiconductor die 12C are stacked in stated order from the bottom. Substrate 11 is a silicon substrate or the like provided with a line inside or on the surface.

In addition, three-dimensional stacked device 10 is an SoC including a plurality of semiconductor dies electrically connected in a three-dimensional stacking method.

For example, bump 30 is used for electrically and mechanically connecting substrate 11 and semiconductor die 12A, and connecting between three semiconductor dies 12. Although there is no limitation on the material of bump 30, bump 30 for example, includes Cu, Ag, Ni, etc., or Sn—Ag—Cu, Sn—Pb, etc. that are solder materials.

In addition, as illustrated in FIG. 2A and FIG. 2B, when focusing on the positional relationship between semiconductor die 12A and semiconductor die 12B, semiconductor die 12B is disposed above semiconductor die 12A such that a portion of semiconductor die 12B does not overlap semiconductor die 12A when viewed in the direction parallel to the Z direction. More specifically, semiconductor die 12B is disposed at a position shifted parallel in a direction parallel to the X direction with respect to semiconductor die 12A.

In addition, when focusing on the positional relationship between semiconductor die 12B and semiconductor die 12C, semiconductor die 12C is disposed above semiconductor die 12B such that a portion of semiconductor die 12C does not overlap semiconductor die 12B when viewed in the direction parallel to the Z direction. More specifically, semiconductor die 12C is disposed at a position shifted parallel in a direction parallel to the X direction with respect to semiconductor die 12B.

As described above, since three-dimensional stacked device 10 has the configuration illustrated in FIG. 2A and FIG. 2B, the positions of heat sources (i.e., heat 20A, heat 20B, and heat 20C) are shifted when viewed in the direction parallel to the Z direction (the stacking direction) as illustrated in FIG. 2B.

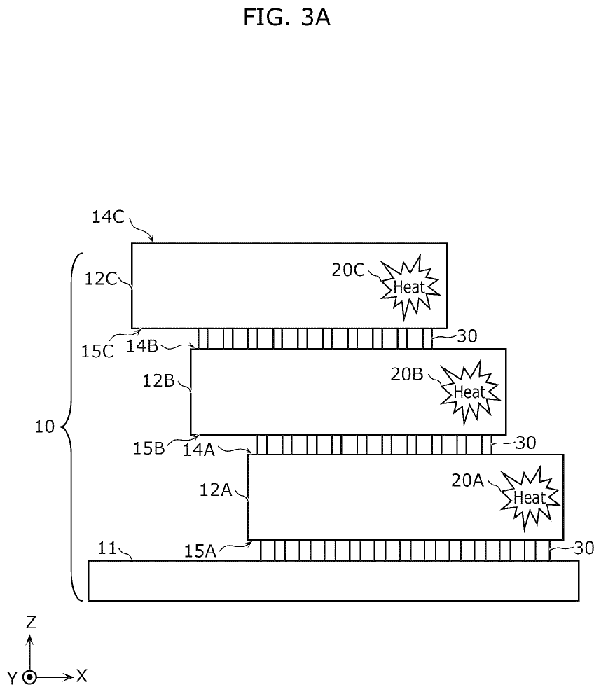

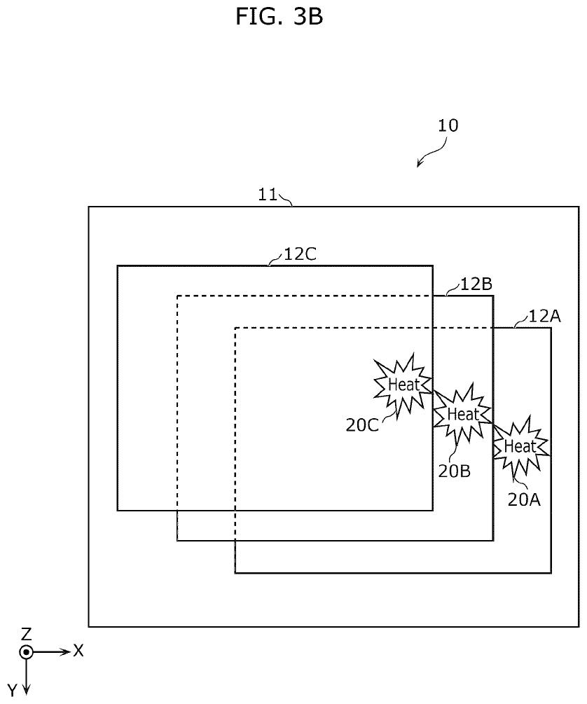

Next, an example of the configuration of three-dimensional stacked device 10 according to Embodiment 1 will be described with reference to FIG. 3A and FIG. 3B. FIG. 3A is a schematic diagram illustrating the configuration of three-dimensional stacked device 10 viewed in a direction parallel to the Y direction. FIG. 3B is a schematic diagram illustrating the configuration of three-dimensional stacked device 10 viewed in the direction parallel to the Z direction. It should be noted that FIG. 3B is a schematic diagram illustrating three-dimensional stacked device 10 illustrated in FIG. 3A when viewed in the direction parallel to the Z direction. The description of FIG. 3A and FIG. 3B will be provided with a focus on the points different from the configuration of three-dimensional stacked device 10 illustrated in FIG. 2A and FIG. 2B.

As illustrated in FIG. 3A and FIG. 3B, when focusing on the positional relationship between semiconductor die 12A and semiconductor die 12B, semiconductor die 12B is disposed above semiconductor die 12A such that a portion of semiconductor die 12B does not overlap semiconductor die 12A when viewed in the direction parallel to the Z direction. More specifically, semiconductor die 12B is dispose at a position shifted parallel in a direction parallel to the X direction and in a direction parallel to the Y direction, with respect to semiconductor die 12A.

In addition, when focusing on the positional relationship between semiconductor die 12B and semiconductor die 12C, semiconductor die 12C is disposed above semiconductor die 12B such that a portion of semiconductor die 12C does not overlap semiconductor die 12B when viewed in the direction parallel to the Z direction. More specifically, semiconductor die 12C is disposed at a position shifted parallel in a direction parallel to the X direction and in a direction parallel to the Y direction, with respect to semiconductor die 12B.

As described above, since three-dimensional stacked device 10 has the configuration illustrated in FIG. 3A and FIG. 3B, the positions of heat sources (i.e., heat 20A, heat 20B, and heat 20C) are shifted when viewed in the direction parallel to the Z direction (the stacking direction) as illustrated in FIG. 3B.

It should be noted that the direction in which semiconductor die 12 is shifted parallel with respect to another semiconductor die 12 may be any direction as long as it is the direction included in the X-Y plane.

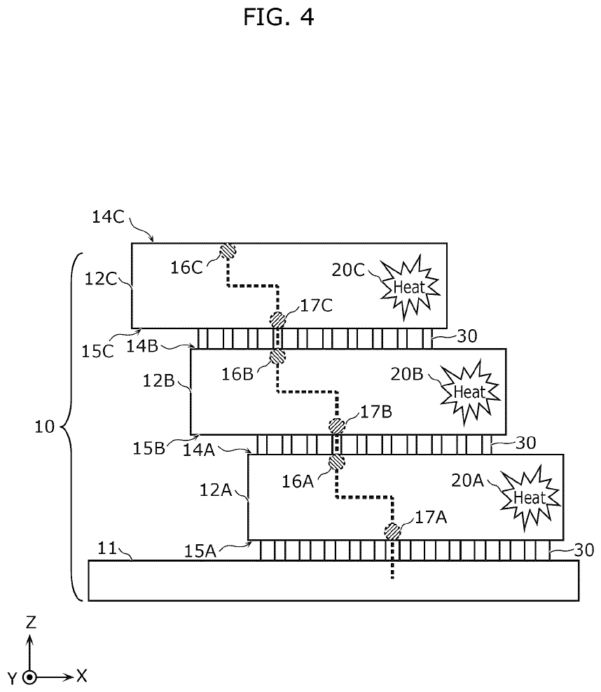

Next, the electrical connection relation of three-dimensional stacked device 10 according to Embodiment 1 will be described. FIG. 4 to FIG. 6B described below are diagrams illustrating the inside of three-dimensional stacked device 10 for explaining the electrical connection relation of three-dimensional stacked device 10.

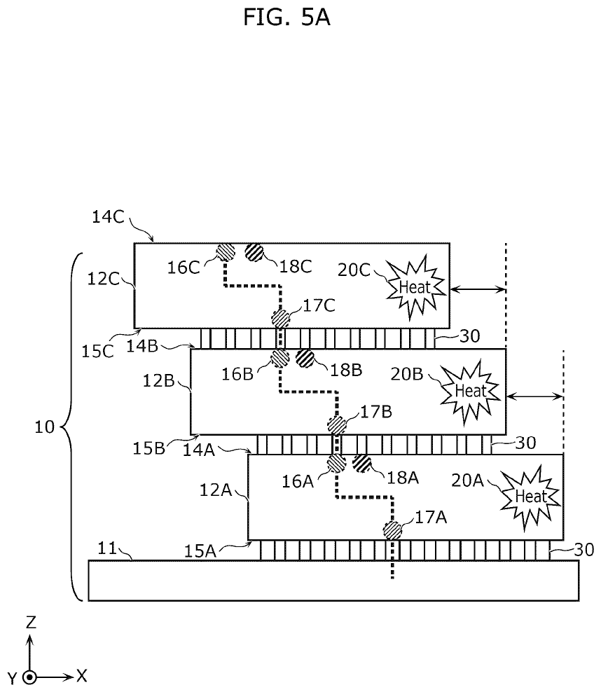

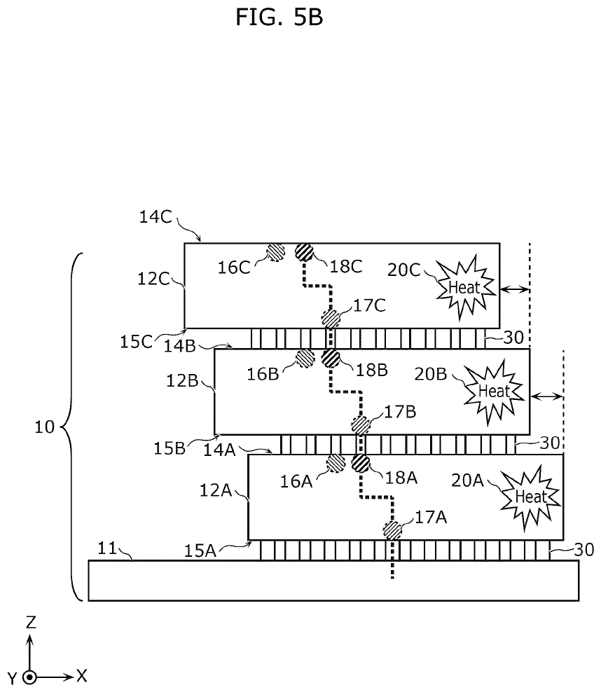

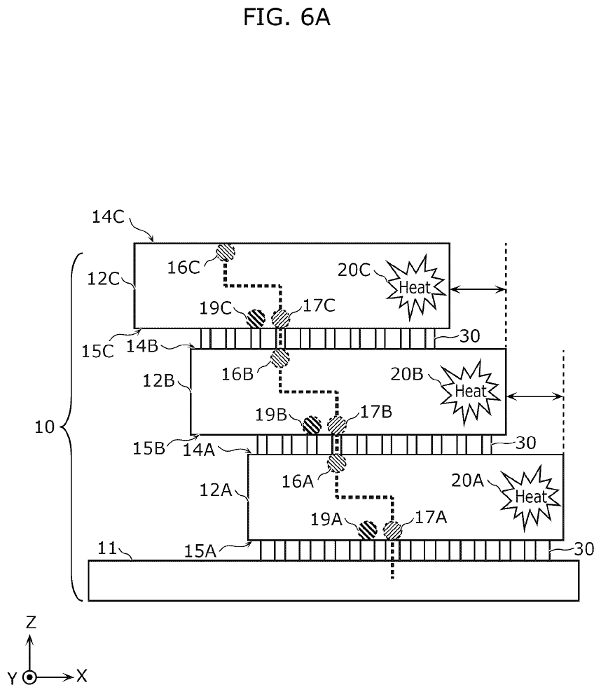

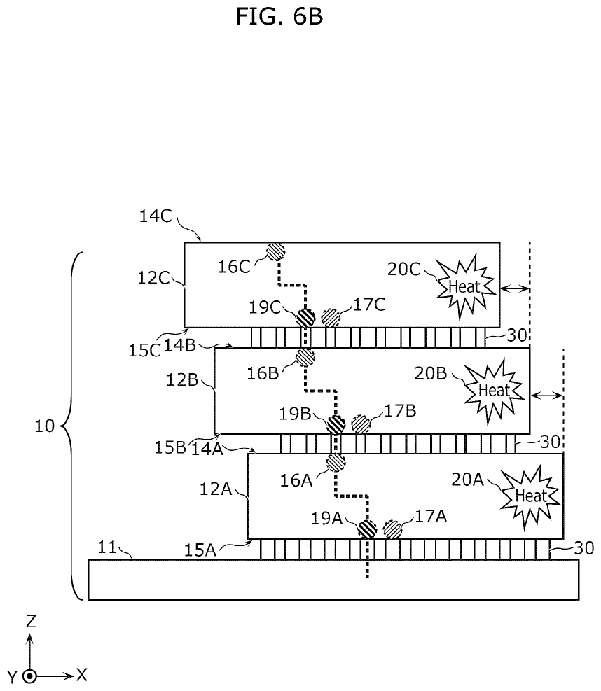

FIG. 4 is a schematic diagram illustrating an example of an electrical connection relation of three-dimensional stacked device 10 according to Embodiment 1. In FIG. 4, three semiconductor dies 12 each include a plurality of first bonding pads 16 and a plurality of second bonding pads 17. In FIG. 4, in order to make the schematic diagram less complicated, only a single first bonding pad 16 and a single second bonding pad 17 are illustrated for each semiconductor die 12. The positions of the plurality of first bonding pads 16 included in semiconductor die 12 used in three-dimensional stacked device 10 illustrated in FIG. 4, when viewed in a direction parallel to the Z direction (the stacking direction), match the positions to which the plurality of second bonding pads 17 are shifted parallel in the plane of bottom surface 15 while maintaining the positional relationship between the plurality of second bonding pads 17. The same also applies to FIG. 5A to FIG. 6B.

In addition, in FIG. 4, the lines extending from the bonding pads are lines schematically indicating the electrical connection between substrate 11 and semiconductor die 12A and the electrical connection between three semiconductor dies 12, and are not lines indicating accurate line paths. The same also applies to FIG. 5A to FIG. 6B.

As illustrated in FIG. 4, when focusing on the connection relation between substrate 11 and semiconductor die 12A, the plurality of second bonding pads 17A included in semiconductor die 12A are electrically connected to substrate 11 via bump 30.

In addition, when focusing on the connection relation between semiconductor die 12A and semiconductor die 12B, the plurality of second bonding pads 17B included in semiconductor die 12B are electrically connected, via bump 30, respectively to the plurality of first bonding pads 16A included in semiconductor die 12A. In other words, semiconductor die 12B is stacked above semiconductor die 12A such that, when viewed in the direction perpendicular to top surface 14 or bottom surface 15, the plurality of second bonding pads 17B included in semiconductor die 12B are electrically connected to the plurality of first bonding pads 16A included in semiconductor die 12A with the positions of the plurality of second bonding pads 17B matching the positions of the plurality of first bonding pads 16A.

In addition, when focusing on the connection relation between semiconductor die 12B and semiconductor die 12C, the plurality of second bonding pads 17C included in semiconductor die 12C are electrically connected respectively to the plurality of first bonding pads 16B included in semiconductor die 12B via bump 30. In other words, semiconductor die 12C is stacked above semiconductor die 12B such that, when viewed in the direction perpendicular to top surface 14 or bottom surface 15 the plurality of second bonding pads 17C included in semiconductor die 12C are electrically connected to the plurality of first bonding pads 16B included in semiconductor die 12B with the positions of the plurality of second bonding pads 17C matching the positions of the plurality of first bonding pads 16B.

Another example of the electrical connection relation of the three-dimensional stacked device according to Embodiment 1 will be described with reference to FIG. 5A and FIG. 5B. FIG. 5A is a schematic diagram illustrating a first connection pattern when three semiconductor dies 12 each include a plurality of first bonding pads 16, a plurality of second bonding pads 17, and a plurality of third bonding pads 18. FIG. 5B is a schematic diagram illustrating a second connection pattern when three semiconductor dies 12 each include a plurality of first bonding pads 16, a plurality of second bonding pads 17, and a plurality of third bonding pads 18.

It should be noted that the three semiconductor dies 12 illustrated in FIG. 5A and FIG. 5B differ from the three semiconductor dies 12 illustrated in FIG. 4 in that each of the three semiconductor dies 12 illustrated in FIG. 5A and FIG. 5B further include a plurality of third bonding pads 18. In addition, in the same manner as FIG. 4, in order to make the schematic diagrams less complicated, only a single first bonding pad 16, a single second bonding pad 17, and a single third bonding pad 18 are illustrated for each semiconductor die 12 in FIG. 5A and FIG. 5B. In addition, the positions of the plurality of third bonding pads 18 included in semiconductor die 12 used in three-dimensional stacked device 10 illustrated in FIG. 5A and FIG. 5B, when viewed in a direction parallel to the Z direction (the stacking direction), match the positions to which the plurality of second bonding pads 17 are shifted parallel in the plane of bottom surface 15 while maintaining the positional relationship between the plurality of second bonding pads 17.

The schematic diagram illustrated in FIG. 5A differs from the schematic diagram illustrated in FIG. 4 in that the plurality of third bonding pads 18 are included, but is same as the schematic diagram illustrated in FIG. 4 in the electrical connection relation between substrate 11 and semiconductor die 12A and the electrical connection relation between the three semiconductor dies 12.

In addition, in regard to FIG. 5B, the electrical connection relation between substrate 11 and semiconductor die 12A is same as the connection relation of the schematic diagram illustrated in FIG. 4. The following describes the points differ from FIG. 4.

As illustrated in FIG. 5B, when focusing on the connection relation between semiconductor die 12A and semiconductor die 12B, the plurality of second bonding pads 17B included in semiconductor die 12B are electrically connected, via bump 30, respectively to the plurality of third bonding pads 18A included in semiconductor die 12A. In other words, semiconductor die 12B is stacked above semiconductor die 12A such that, when viewed in the direction perpendicular to top surface 14 or bottom surface 15, the plurality of second bonding pads 17B included in semiconductor die 12B are electrically connected to the plurality of third bonding pads 18A included in semiconductor die 12A with the positions of the plurality of second bonding pads 17B matching the positions of the plurality of third bonding pads 18A.

In addition, when focusing on the connection relation between semiconductor die 12B and semiconductor die 12C, the plurality of second bonding pads 17C included in semiconductor die 12C are electrically connected, via bump 30, respectively to the plurality of third bonding pads 18B included in semiconductor die 12B. In other words, semiconductor die 12C is stacked above semiconductor die 12B such that, when viewed in the direction perpendicular to top surface 14 or bottom surface 15, the plurality of second bonding pads 17C included in semiconductor die 12C are electrically connected to the plurality of third bonding pads 18B included in semiconductor die 12B with the positions of the plurality of second bonding pads 17C matching the positions of the plurality of third bonding pads 18B.

Here, when comparing FIG. 5A with FIG. 5B, the distance in which semiconductor die 12B is shifted parallel with respect to semiconductor die 12A (i.e., the length of the double-headed arrow) and the distance in which semiconductor die 12C is shifted parallel with respect to semiconductor die 12B (i.e., the length of the double-headed arrow) differ from each other. The length of the double-headed arrow corresponds to the distance in which the positions of the plurality of second bonding pads 17 included in semiconductor die 12 are shifted parallel in the X-Y plane such that, when viewed in the direction parallel to the Z direction, the positions of the plurality of second bonding pads 17 match the positions of the plurality of first bonding pads 16 or the plurality of third bonding pads 18 included in semiconductor die 12.

As described above, semiconductor die 12 includes the plurality of first bonding pads 16 and the plurality of third bonding pads 18 each disposed on top surface 14 and a plurality of second bonding pads 17 each disposed on bottom surface 15. As a result, when stacking the plurality of semiconductor dies 12, the user can select as appropriate bonding pads to be connected to the plurality of second bonding pads 17 from among the plurality of first bonding pads 16 and the plurality of third bonding pads 18.

It should be noted that FIG. 5A and FIG. 5B illustrate the case where all the above-described distances of parallel shift are the same, but the present disclosure is not limited to this case. For example, the plurality of second bonding pads 17B included in semiconductor die 12B may be electrically connected, via bump 30, respectively to the plurality of first bonding pads 16A included in semiconductor die 12A, and the plurality of second bonding pads 17C included in semiconductor die 12C may be electrically connected, via bump 30, respectively to the plurality of third bonding pads 18B included in semiconductor die 12B.

Yet another example of the electrical connection relation of three-dimensional stacked device 10 according to Embodiment 1 will be described with reference to FIG. 6A and FIG. 6B. FIG. 6A is a schematic diagram illustrating a first connection pattern when three semiconductor dies 12 each include a plurality of first bonding pads 16, a plurality of second bonding pads 17, and a plurality of fourth bonding pads 19. FIG. 6B is a schematic diagram illustrating a second connection pattern when three semiconductor dies 12 each include a plurality of first bonding pads 16, a plurality of second bonding pads 17, and a plurality of fourth bonding pads 19.

It should be noted that the three semiconductor dies 12 illustrated in FIG. 6A and FIG. 6B differ from the three semiconductor dies 12 illustrated in FIG. 4 in that each of the three semiconductor dies 12 illustrated in FIG. 6A and FIG. 6B further include a plurality of fourth bonding pads 19. In addition, in the same manner as FIG. 4, in order to make the schematic diagrams less complicated, only a single first bonding pad 16, a single second bonding pad 17, and a single fourth bonding pad 19 are illustrated for each semiconductor die 12 in FIG. 6A and FIG. 6B. In addition, when viewed in a direction parallel to the Z direction (the stacking direction), the positions of the plurality of first bonding pads 16 included in semiconductor die 12 used in three-dimensional stacked device 10 illustrated in FIG. 6A and FIG. 6B match the positions to which the plurality of fourth bonding pads 19 are shifted parallel in the plane of bottom surface 15 while maintaining the positional relationship between the plurality of fourth bonding pads 19.

The schematic diagram illustrated in FIG. 6A differs from the schematic diagram illustrated in FIG. 4 in that the plurality of fourth bonding pads 19 are included, but is same as the schematic diagram illustrated in FIG. 4 in the electrical connection relation between substrate 11 and semiconductor die 12A and the electrical connection relation between the three semiconductor dies 12.

As illustrated in FIG. 6B, when focusing on the connection relation between substrate 11 and semiconductor die 12A, the plurality of fourth bonding pads 19A included in semiconductor die 12A are electrically connected, via bump 30, to substrate 11.

In addition, focusing on the connection relation between semiconductor die 12A and semiconductor die 12B, the plurality of fourth bonding pads 19B included in semiconductor die 12B are electrically connected, via bump 30, respectively to the plurality of first bonding pads 16A included in semiconductor die 12A. In other words, semiconductor die 12B is stacked above semiconductor die 12A such that, when viewed in the direction perpendicular to top surface 14 or bottom surface 15, the plurality of fourth bonding pads 19B included in semiconductor die 12B are electrically connected to the plurality of first bonding pads 16A included in semiconductor die 12A with the positions of the plurality of fourth bonding pads 19B matching the positions of the plurality of first bonding pads 16A.

In addition, when focusing on the connection relation between semiconductor die 12B and semiconductor die 12C, the plurality of fourth bonding pads 19C included in semiconductor die 12C are electrically connected, via bump 30, respectively to the plurality of first bonding pads 16B included in semiconductor die 12B. In other words, semiconductor die 12C is stacked above semiconductor die 12B such that, when viewed in the direction perpendicular to top surface 14 or bottom surface 15, the plurality of fourth bonding pads 19C included in semiconductor die 12C are electrically connected to the plurality of first bonding pads 16B included in semiconductor die 12B with the positions of the plurality of fourth bonding pads 19C matching the positions of the plurality of first bonding pads 16B.

Here, when comparing FIG. 6A with FIG. 6B, the distance in which semiconductor die 12B is shifted parallel with respect to semiconductor die 12A (i.e., the length of the double-headed arrow) and the distance in which semiconductor die 12C is shifted parallel with respect to semiconductor die 12B (i.e., the length of the double-headed arrow) differ from each other. The length of the double-headed arrow corresponds to the distance in which the positions of the plurality of second bonding pads 17 or the positions of the plurality of fourth bonding pads 19 included in semiconductor die 12 are shifted parallel in the X-Y plane such that, when viewed in the direction parallel to the Z direction, the positions of the plurality of second bonding pads 17 or the positions of the plurality of fourth bonding pads 19 match the positions of the plurality of first bonding pads 16 included in semiconductor die 12.

As described above, semiconductor die 12 includes the plurality of first bonding pads 16 disposed on top surface 14 and a plurality of second bonding pads 17 and the plurality of fourth bonding pads 19 disposed on bottom surface 15. As a result, when stacking the plurality of semiconductor dies 12, the user can select as appropriate bonding pads to be connected to the plurality of first bonding pads 16 from among the plurality of second bonding pads 17 and the plurality of fourth bonding pads 19.

It should be noted that FIG. 6A and FIG. 6B illustrate the case where all the above-described distances of parallel shift are the same, but the present disclosure is not limited to this case. For example, the plurality of second bonding pads 17B included in semiconductor die 12B may be electrically connected, via bump 30, respectively to the plurality of first bonding pads 16A included in semiconductor die 12A, and the plurality of fourth bonding pads 19C included in semiconductor die 12C may be electrically connected, via bump 30, respectively to the plurality of first bonding pads 16B included in semiconductor die 12B.

### Comparison Example

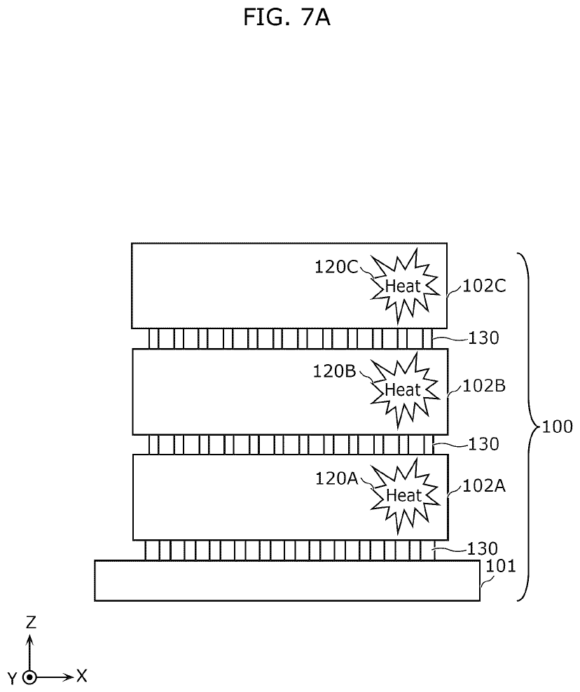

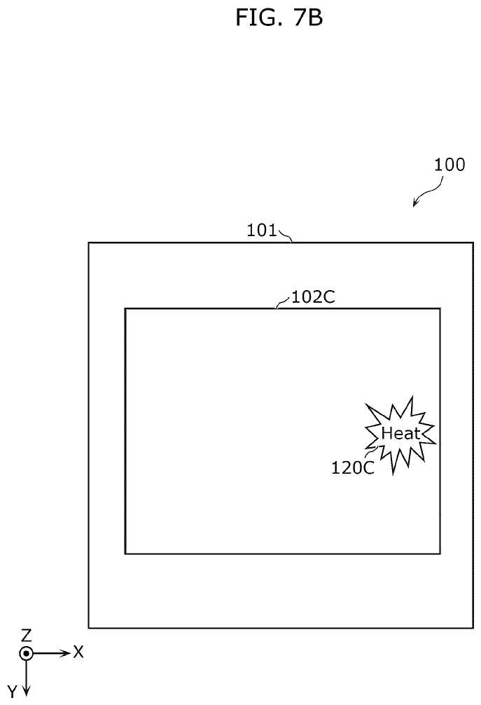

Next, as a comparison example, conventional three-dimensional stacked device 100 will be described with reference to FIG. 7A and FIG. 7B. FIG. 7A is a schematic diagram illustrating the configuration of three-dimensional stacked device 100 viewed in a direction parallel to the Y direction. FIG. 7B is a schematic diagram illustrating the configuration of three-dimensional stacked device 100 viewed in a direction parallel to the Z direction. It should be noted that FIG. 7B is a schematic diagram illustrating three-dimensional stacked device 100 illustrated in FIG. 7A viewed in a direction parallel to the Z direction.

As illustrated in FIG. 7A, three-dimensional stacked device 100 includes substrate 101, semiconductor die 102A, semiconductor die 102B, semiconductor die 102C, and bump 130. In three-dimensional stacked device 100, substrate 101, semiconductor die 102A, semiconductor die 102B, and semiconductor die 102C are stacked in stated order from the bottom.

Substrate 101 is a silicon substrate or the like provided with a line inside or on the surface as with substrate 11.

Semiconductor die 102A, semiconductor die 102B, and semiconductor die 102C are semiconductor chips that are identical in shape and configuration. In the description below, when it is not necessary to specifically differentiate them, they may be simply referred to as “semiconductor die 102”.

Bump 130 electrically and mechanically connects substrate 101 and semiconductor die 102A and connects between three semiconductor dies 102 in the same manner as bump 30.

Heat 120A indicates the position of main heat source that generates heat in semiconductor die 102A when three-dimensional stacked device 100 is performing an operation. Heat 120A indicated in semiconductor die 102A is a mark indicating the location where the amount of heat generated inside semiconductor die 102A is particularly large. The same is true for heat 120B and heat 120C. Accordingly, when three-dimensional stacked device 100 in which three semiconductor dies 102 which are same in configuration are stacked is performing an operation, the positions of the heat sources of the three semiconductor dies 102 are same when comparing between the respective semiconductor dies 102.

In addition, as illustrated in FIG. 7A and FIG. 7B, the three semiconductor dies 102 are stacked to overlap when viewed in the direction parallel to the Z direction. More specifically, when viewed in the direction parallel to the Z direction, the three semiconductor dies 102 are stacked with four vertexes of each of the three semiconductor dies 102 overlapping one another. In other words, in three-dimensional stacked device 100, the positions of the heat sources (i.e., heat 120A, 120B, and 120C) match when viewed in the direction parallel to the Z direction (the stacking direction), as illustrated in FIG. 7B.

### Advantageous Effects, Etc

As described above, semiconductor die 12 according to the present embodiment is semiconductor die 12 that is used in three-dimensional stacked device 10 including a plurality of semiconductor dies 12 which are same in configuration and stacked on one another, the plurality of semiconductor dies 12 each being semiconductor die 12. Semiconductor die 12 includes: main body 13 including top surface 14 and bottom surface 15; a plurality of first bonding pads 16 disposed on top surface 14; and a plurality of second bonding pads 17 disposed on bottom surface 15. In semiconductor die 12, top surface 14 is one of principal surfaces of main body 14, bottom surface 15 is a surface opposing top surface 14, when viewed in a direction perpendicular to top surface 14 or bottom surface 15, the plurality of first bonding pads 16 are disposed at positions that match positions to which the plurality of second bonding pads 17 are shifted in a certain way in a plane of bottom surface 15 while maintaining a positional relationship between the plurality of second bonding pads 17.

According to this configuration, in semiconductor die 12, when viewed in a direction perpendicular to top surface 14 or bottom surface 15, the positions of the plurality of first bonding pads 16 match the positions to which the plurality of second bonding pads 17 are shifted in the plane of bottom surface 15 while maintaining the positional relationship between the plurality of second bonding pads 17. In other words, when the plurality of semiconductor dies 12 are stacked, the position of the main heat source that generates heat in each semiconductor die 12 can be shifted. As a result, semiconductor die 12 is capable of reducing the density of heat sources in three-dimensional stacked device 10 to be smaller than the density of heat sources in three-dimensional stacked device 100 of the comparison example. It is thus possible to more efficiently dissipate heat generated inside three-dimensional stacked device 10 (i.e., SoC) that includes the plurality of semiconductor dies 12 which are stacked and same in configuration.

In addition, in semiconductor die 12 according to the present embodiment, the certain way in which the positions of the plurality of second bonding pads 17 are shifted in the plane of bottom surface 15 while maintaining the positional relationship between the plurality of second bonding pads 17 is parallel shift in the plane of the bottom surface.

According to this configuration, semiconductor die 12 is located at a position where the plurality of first bonding pads 16 do not overlap the plurality of second bonding pads 17 when viewed in a direction perpendicular to top surface 14 or bottom surface 15, and thus when the plurality of semiconductor dies 12 are stacked, the position of the main heat source that generates heat in each semiconductor die 12 can be shifted. As a result, it is possible to more efficiently dissipate heat generated inside three-dimensional stacked device 10 (i.e., SoC) that includes the plurality of semiconductor dies 12 which are stacked and same in configuration.

In addition, in semiconductor die 12 according to the present embodiment, a plurality of third bonding pads 18 disposed on top surface 14 of main body 13 are included. In semiconductor die 12, when viewed in the direction perpendicular to top surface 14 or bottom surface 15, the plurality of third bonding pads 18 are disposed at positions that match positions to which the plurality of second bonding pads 17 are shifted in the certain way in the plane of bottom surface 15 while maintaining the positional relationship between the plurality of second bonding pads 17, and the plurality of third bonding pads 18 are electrically connected one to one to the plurality of first bonding pads 16 disposed on main body 13 where the plurality of third bonding pads 18 are disposed.

According to this configuration, semiconductor die 12 further includes a plurality of third bonding pads 18 disposed on top surface 14, and thus when stacking the plurality of semiconductor dies 12, a user can select as appropriate bonding pads to be connected to the plurality of second bonding pads 17 from among the plurality of first bonding pads 16 and the plurality of third bonding pads 18. As a result, it is possible for the user to change the electrical connection paths of the plurality of semiconductor dies 12 according to the amount of heat generated in each semiconductor die 12.

In addition, in semiconductor die 12 according to the present embodiment, a plurality of fourth bonding pads 19 disposed on bottom surface 15 of main body 13 are included. In semiconductor die 12, when viewed in the direction perpendicular to top surface 14 or bottom surface 15, the plurality of first bonding pads 16 are disposed at positions that match positions to which the plurality of fourth bonding pads 19 are shifted in the certain way in the plane of bottom surface 15 while maintaining a positional relationship between the plurality of fourth bonding pads 19, and the plurality of fourth bonding pads 19 are electrically connected one to one to the plurality of second bonding pads 17 disposed on main body 13 where the plurality of fourth bonding pads 19 are disposed.

According to this configuration, semiconductor die 12 further includes a plurality of fourth bonding pads 19 disposed on bottom surface 15, and thus when stacking the plurality of semiconductor dies 12, a user can select as appropriate bonding pads to be connected to the plurality of first bonding pads 16 from among the plurality of second bonding pads 17 and the plurality of fourth bonding pads 19. As a result, it is possible for the user to change the electrical connection paths of the plurality of semiconductor dies 12 according to the amount of heat generated in each semiconductor die 12.

In addition, three-dimensional stacked device 10 according to the present embodiment is three-dimensional stacked device 10 having a configuration in which a plurality of semiconductor dies 12 according to the present disclosure are stacked. In three-dimensional stacked device 10, the plurality of semiconductor dies include first semiconductor die 12 and second semiconductor die 12, and when viewed in the direction perpendicular to top surface 14 or bottom surface 15, second semiconductor die 12 is stacked above first semiconductor die 12, with positions of the plurality of second bonding pads 17 included in second semiconductor die 12 matching positions of the plurality of first bonding pads 16 included in first semiconductor die 12.

According to this configuration, the plurality of semiconductor dies 12 are stacked in a state in which the position of the main heat source that generates heat in each semiconductor die 12 is shifted, and thus three-dimensional stacked device 10 is capable of reducing the density of the heat source to be smaller than three-dimensional stacked device 100 of the comparison example. As a result, it is possible for three-dimensional stacked device 10 (i.e., SoC) to more efficiently dissipate heat generated inside.

In addition, in three-dimensional stacked device 10 according to the present embodiment, when viewed in the direction perpendicular to top surface 14 or bottom surface 15, second semiconductor die 12 is stacked above first semiconductor die 12 with a portion of second semiconductor die 12 not overlapping first semiconductor die 12.

According to this configuration, in a region in which the portion of second semiconductor die 12 does not overlap first semiconductor die 12, it is easier to dissipate heat than in a region in which two semiconductor dies overlap, and thus three-dimensional stacked device 10 (i.e., SoC) is capable of more efficiently dissipating heat generated inside.

In addition, three-dimensional stacked device 10 according to the present embodiment is three-dimensional stacked device 10 having a configuration in which the plurality of semiconductor dies 12 according to the present disclosure are stacked. In three-dimensional stacked device 10, the plurality of semiconductor dies include first semiconductor die 12 and second semiconductor die 12, and second semiconductor die 12 is stacked above first semiconductor die 12: with positions of the plurality of second bonding pads 17 included in second semiconductor die 12 matching positions of the plurality of first bonding pads 16 included in first semiconductor die 12, when viewed in the direction perpendicular to top surface 14 or bottom surface 15; or with the positions of the plurality of second bonding pads 17 included in second semiconductor die 12 matching positions of the plurality of third bonding pads 18 included in first semiconductor die 12, when viewed in the direction perpendicular to top surface 14 or bottom surface 15.

According to this configuration, three-dimensional stacked device 10 described here yields advantageous effects equivalent to the advantageous effects of the above-described three-dimensional stacked device 10. In addition, when stacking the plurality of semiconductor dies 12 above first semiconductor die 12, a user can select as appropriate bonding pads to be connected to the plurality of second bonding pads 17 from among the plurality of first bonding pads 16 and the plurality of third bonding pads 18. As a result, it is possible for a user to change the electrical connection paths of the plurality of semiconductor dies 12 according to the amount of heat generated in each semiconductor die 12.

In addition, three-dimensional stacked device 10 according to the present embodiment is three-dimensional stacked device 10 having a configuration in which a plurality of semiconductor dies 12 according to the present disclosure are stacked. In three-dimensional stacked device 10, the plurality of semiconductor dies include first semiconductor die 12 and second semiconductor die 12, and second semiconductor die 12 is stacked above first semiconductor die 12: with positions of the plurality of second bonding pads 17 included in second semiconductor die 12 matching positions of the plurality of first bonding pads 16 included in first semiconductor die 12, when viewed in the direction perpendicular to top surface 14 or bottom surface 15; or with positions of the plurality of fourth bonding pads 19 included in second semiconductor die 12 matching the positions of the plurality of first bonding pads 16 included in first semiconductor die 12, when viewed in the direction perpendicular to top surface 14 or bottom surface 15.

According to this configuration, three-dimensional stacked device 10 described here yields advantageous effects equivalent to the advantageous effects of the above-described three-dimensional stacked device 10. In addition, when stacking second semiconductor die 12 above first semiconductor die 12, a user can select as appropriate bonding pads to be connected to the plurality of first bonding pads 16 from among the plurality of second bonding pads 17 and the plurality of fourth bonding pads 19. As a result, it is possible for the user to change the electrical connection paths of the plurality of semiconductor dies 12 according to the amount of heat generated in each semiconductor die 12.

### Embodiment 2

Next, Embodiment 2 will be described. In the present embodiment, the positional relationship between the bonding pad disposed on top surface 14 of semiconductor die 12 (i.e., a plurality of first bonding pads 16 and a plurality of third bonding pads 18) and the bonding pad disposed on bottom surface 15 (i.e., a plurality of second bonding pads 17 and a plurality of fourth bonding pads 19) differs that of Embodiment 1. The present embodiment will be described with a focus on the points different from Embodiment 1 described above.

### Semiconductor Die

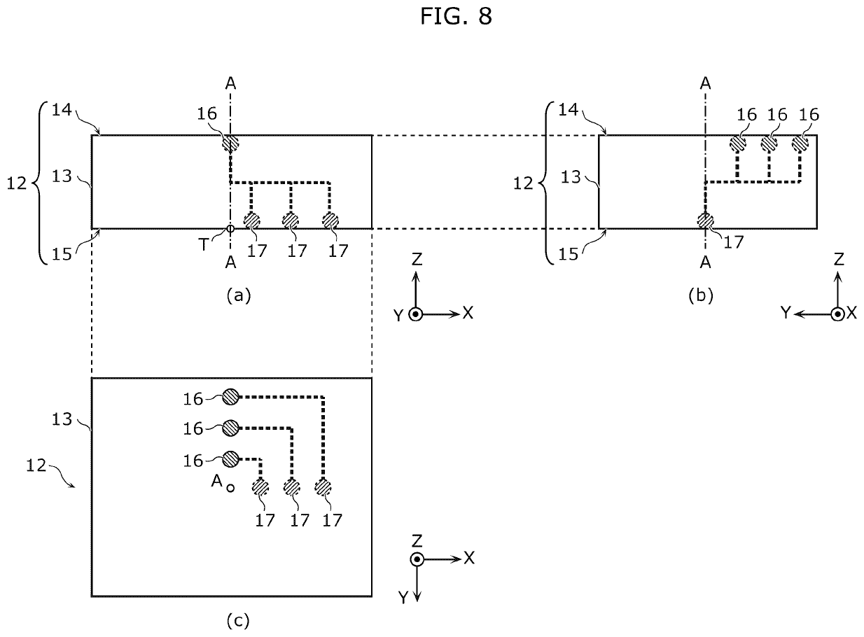

FIG. 8 is a schematic diagram illustrating an example of a configuration of semiconductor die 12 according to Embodiment 2. In FIG. 8, in order to make the schematic diagram less complicated, an example of a configuration of semiconductor die 12 in which the plurality of third bonding pads 18 and the plurality of fourth bonding pads 19 are not included is illustrated. FIG. 8 is also a diagram illustrating the inside of semiconductor die 12 for explaining the configuration of semiconductor die 12. Line A-A illustrated in FIG. 8 is a straight line passing through predetermined point T that is located on bottom surface 15, and is in parallel with the Z direction. In FIG. 8, (a) is a schematic diagram illustrating the configuration of semiconductor die 12 when viewed in a direction parallel to the Y direction. In FIG. 8, (b) is a schematic diagram illustrating the configuration of semiconductor die 12 when viewed in a direction parallel to the X direction. In FIG. 8, (c) is a schematic diagram illustrating the configuration of semiconductor die 12 when viewed in a direction parallel to the Z direction.

As illustrated in FIG. 8, the plurality of first bonding pads 16 are aligned in the Y direction and the plurality of second bonding pads 17 are aligned in the X direction. In other words, when viewed in a direction perpendicular to top surface 14 or bottom surface 15, the positions of the plurality of first bonding pads 16 match the positions to which the plurality of second bonding pads 17 are shifted in the plane of bottom surface 15 while maintaining the positional relationship between the plurality of second bonding pads 17. More specifically, as illustrated in (c) of FIG. 8, the positions of the plurality of second bonding pads 17 match the positions of the plurality of first bonding pads 16 when the plurality of second bonding pads 17 are rotationally shifted counterclockwise by 90 degrees about line A-A (i.e., predetermined point T located on bottom surface 15) in the X-Y plane and viewed in a direction parallel to the Z direction. It should be noted that, when bottom surface 15 of semiconductor die 12 has a quadrilateral shape, predetermined point T may be the intersection point of the diagonal lines of the quadrilateral shape.

In addition, a plurality of third bonding pads 18 and a plurality of fourth bonding pads 19 may be provided. For example, a plurality of third bonding pads 18 may be arranged such that the positions of the plurality of second bonding pads 17 match the positions of the plurality of third bonding pads 18 when the plurality of second bonding pads 17 are rotationally shift counterclockwise by 45 degrees about predetermined point T in the X-Y plane and viewed in a direction parallel to the Z direction. In addition, a plurality of fourth bonding pads 19 may be arranged such that the positions of the plurality of fourth bonding pads 19 match the positions of the plurality of first bonding pads 16 when the plurality of fourth bonding pads 19 are rotationally shifted counterclockwise by 135 degrees about predetermined point T in the X-Y plane and viewed in a direction parallel to the Z direction. It should be noted that the angles indicated above are merely examples, and thus any angles other than those indicated above may be employed.

Furthermore, the positional relationship between the plurality of first bonding pads 16 and the plurality of second bonding pads 17 may be the positional relationship in which the parallel shift described in FIG. 1 and the rotational shift described in FIG. 8 are combined. In other words, the plurality of second bonding pads 17 may be arranged such that the positions of the plurality of second bonding pads 17 match the positions of the plurality of first bonding pads 16 when the plurality of second bonding pads 17 are: shifted parallel in the X-Y plane with respect to the plurality of first bonding pads 16; rotationally shifted about predetermined point T in the X-Y plane; and viewed in a direction parallel to the Z direction. The same is true for the case where semiconductor die 12 includes the plurality of third bonding pads 18 and the plurality of fourth bonding pads 19.

It should be noted that the angles indicated in the description of FIG. 8 are merely examples, and thus any angles other than those indicated above such as 30 degrees or 60 degrees may be employed.

Furthermore, the plurality of first bonding pads 16, the plurality of second bonding pads 17, the plurality of third bonding pads 18, and the plurality of fourth bonding pads 19 need not respectively be aligned when viewed in any of the directions on X-Y plane.

### [Three-Dimensional Stacked Device]

The following describes the three-dimensional stacked device having a configuration in which a plurality of semiconductor dies 12 each being the above-described semiconductor die 12 are stacked. In addition, although the three-dimensional stacked device in which three semiconductor dies 12 are stacked will be exemplified in the following description, any three-dimensional stacked devices are included in the present disclosure as long as the three-dimensional stacked device includes at least two semiconductor dies 12 stacked therein. In addition, in the following description, an additional character of “A”, “B”, or “C” is added to numerical references as in semiconductor die 12A, 12B, or 12C. Semiconductor dies 12A, 12B, and 12C are each semiconductor die 12 having the same configuration, but are differentiated for making the description easier to understand. Therefore, when it is not necessary to specifically differentiate them, they may be simply referred to as “semiconductor die 12”. Furthermore, an additional character of “A”, “B”, or “C” is added to numerical references of the structural components included in semiconductor dies 12A, 12B, and 12C for the same reason. Therefore, when it is not necessary to specifically differentiate them, they may be described without the additional character of “A”, “B”, or “C”.

In addition, in the following description, the position of main heat source that generates heat in semiconductor die 12 when the three-dimensional stacked device is performing an operation is indicated as heat 20. Heat 20 indicated in semiconductor die 12 is a mark indicating the location where the amount of heat generated inside semiconductor die 12 is particularly large. Accordingly, when the three-dimensional stacked device in which a plurality of semiconductor dies 12 having the same configuration are stacked is performing an operation, the positions of the heat sources of the respective semiconductor dies 12 are same when the individual semiconductor dies 12 are compared. Furthermore, an additional character of “A”, “B”, or “C” is also added to numerical references of heat 20 indicated in semiconductor dies 12A, 12B, and 12C for making the description easier to understand. Therefore, when it is not necessary to specifically differentiate them, they may be described without the additional character of “A”, “B”, or “C”.

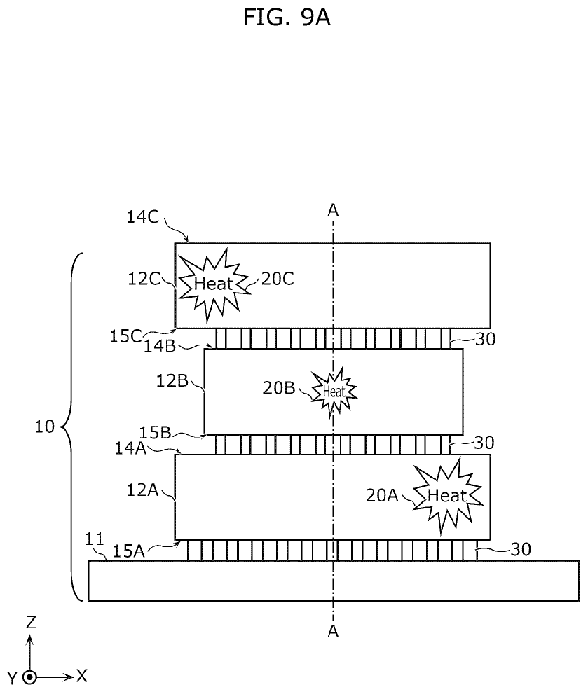

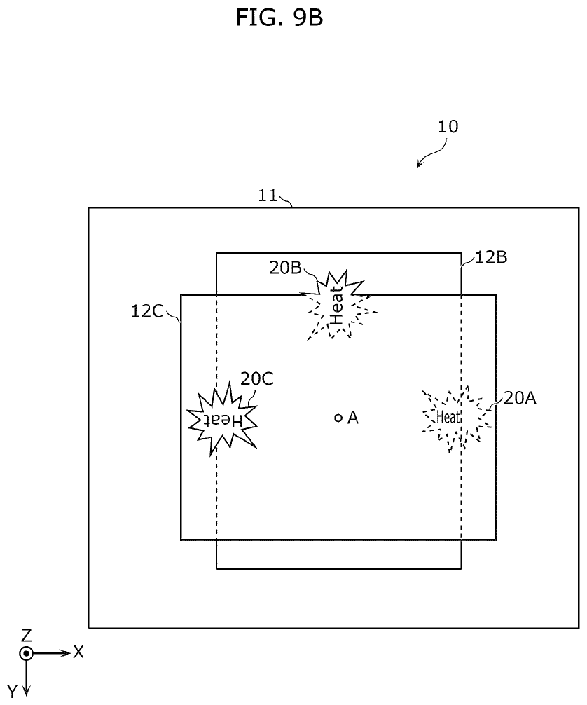

An example of a configuration of three-dimensional stacked device 10 according to Embodiment 2 will be described with reference to FIG. 9A and FIG. 9B. FIG. 9A is a schematic diagram illustrating the configuration of three-dimensional stacked device 10 when viewed in a direction parallel to the Y direction. FIG. 9B is a schematic diagram illustrating the configuration of three-dimensional stacked device 10 when viewed in a direction parallel to the Z direction. It should be noted that FIG. 9B is a schematic diagram illustrating three-dimensional stacked device 10 illustrated in FIG. 9A when viewed in a direction parallel to the Z direction.

AS illustrated in FIG. 9A and FIG. 9B, when focusing on the positional relationship between semiconductor die 12A and semiconductor die 12B, semiconductor die 12B is rotationally shifted counterclockwise by 90 degrees about line A-A as a central axis with respect to semiconductor die 12A.

In addition, when focusing on the positional relationship between semiconductor die 12B and semiconductor die 12C, semiconductor die 12C is rotationally shifted counterclockwise by 90 degrees about line A-A as a central axis with respect to semiconductor die 12B.

As described above, since three-dimensional stacked device 10 has the configuration as illustrated in FIG. 9A and FIG. 9B, the positions of heat sources (i.e., heat 20A, heat 20B, and heat 20C) are shifted when viewed in the direction parallel to the Z direction (the stacking direction) as illustrated in FIG. 9B. In this manner, three-dimensional stacked device 10 is capable of reducing the density of the heat sources to be smaller than the density of the heat sources of three-dimensional stacked device 100 according to the comparison example.

In addition, when viewed in the direction parallel to the Z direction (the stacking direction) as illustrated in FIG. 9B, in the case where the shape of semiconductor die 12 is not square, there is a region where a portion of the two semiconductor dies 12 connected by bump 30 does not overlap. With this configuration, heat dissipation is more facilitated in the region where a portion of the two semiconductor dies 12 does not overlap than in the region where the two semiconductor dies 12 overlap, and thus three-dimensional stacked device 10 is capable of more efficiently dissipating heat.

In addition, when viewed in the direction parallel to the Z direction (the stacking direction) as illustrated in FIG. 9B, in the case where the shape of semiconductor die 12 is square, the two semiconductor dies 12 connected by bump 30 overlap. In other words, when viewed in the direction parallel to the Z direction, the two semiconductor dies are stacked with four vertexes of each of the two semiconductor dies overlapping one another. Such three-dimensional stacked device 10 has the same shape as the shape of three-dimensional stacked device 100 according to the comparison example, and thus a design change from three-dimensional stacked device 100 according to the comparison example is readily carried out.

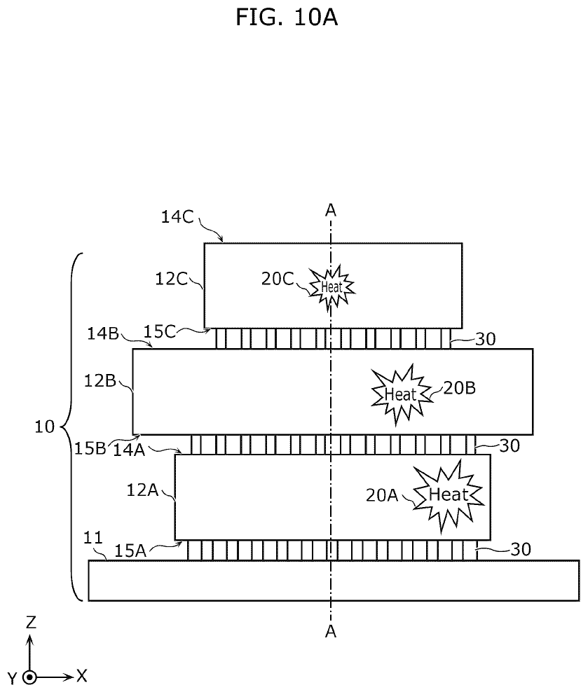

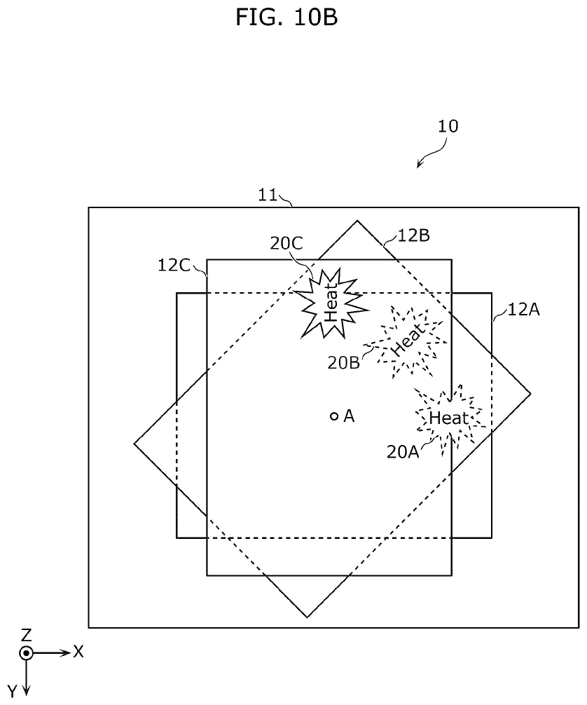

Next, another example of the configuration of three-dimensional stacked device 10 according to Embodiment 2 will be described with reference to FIG. 10A and FIG. 10B. FIG. 10A is a schematic diagram illustrating the configuration of three-dimensional stacked device 10 when viewed in a direction parallel to the Y direction. FIG. 10B is a schematic diagram illustrating the configuration of three-dimensional stacked device 10 when viewed in a direction parallel to the Z direction. FIG. 10B is a schematic diagram illustrating three-dimensional stacked device 10 illustrated in FIG. 10A when viewed in a direction parallel to the Z direction.

As illustrated in FIG. 10A and FIG. 10B, when focusing on the positional relationship between semiconductor die 12A and semiconductor die 12B, semiconductor die 12B is rotationally shifted counterclockwise by 45 degrees about line A-A as a central axis, with respect to semiconductor die 12A.

In addition, when focusing on the positional relationship between semiconductor die 12B and semiconductor die 12C, semiconductor die 12C is rotationally shifted counterclockwise by 45 degrees about line A-A as a central axis, with respect to semiconductor die 12B.

As described above, since three-dimensional stacked device 10 has the configuration as illustrated in FIG. 10A and FIG. 10B, the positions of heat sources (i.e., heat 20A, heat 20B, and heat 20C) are shifted when viewed in the direction parallel to the Z direction (the stacking direction) as illustrated in FIG. 10B. In this manner, three-dimensional stacked device 10 is capable of reducing the density of the heat sources to be smaller than the density of the heat sources of three-dimensional stacked device 100 according to the comparison example.

It should be noted that the angles indicated in the description of FIG. 9A to FIG. 10B are merely examples, and thus any angles other than those indicated above, such as 30 degrees or 60 degrees, may be employed.

In addition, in the descriptions of FIG. 9A to FIG. 10B, the case where all of the angles by which the above-described rotational shifts are performed are the same has been indicated, but the present disclosure is not limited to this case. For example, semiconductor die 12B may be rotationally shifted counterclockwise by 90 degrees about line A-A as a central axis with respect to semiconductor die 12A, and semiconductor die 12C may be rotationally shifted counterclockwise by 45 degrees about line A-A as a central axis with respect to semiconductor die 12B.

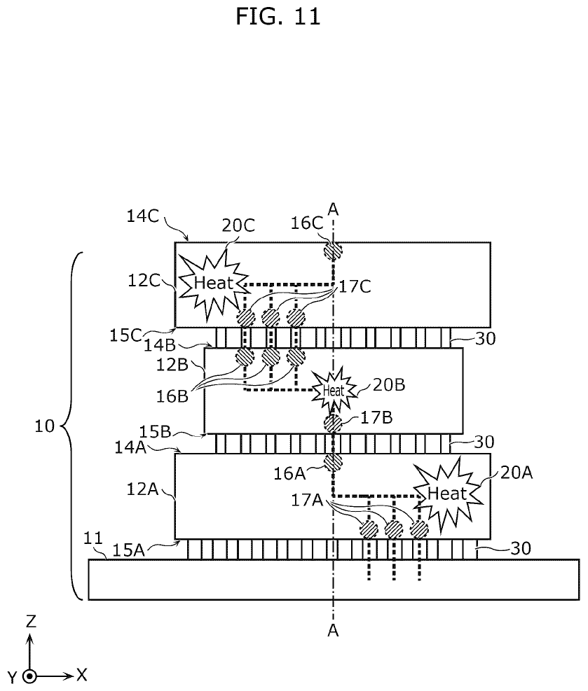

Next, the electrical connection relation of three-dimensional stacked device 10 according to the present embodiment will be described with reference to FIG. 11. FIG. 11 is a schematic diagram illustrating an electrical connection relation of three-dimensional stacked device 10 illustrated in FIG. 9A and FIG. 9B. It should be noted that the positions of the plurality of first bonding pads 16 included in semiconductor die 12 used in three-dimensional stacked device 10 illustrated in FIG. 11 match the positions to which the plurality of second bonding pads 17 are rotationally shifted counterclockwise by 90 degrees about line A-A as a central axis in the plane of bottom surface 15 while maintaining the positional relationship between the plurality of second bonding pads 17 when viewed in a direction parallel to the Z direction (the stacking direction). In FIG. 11, in order to make the schematic diagram less complicated, an example of a configuration of semiconductor die 12 in which the plurality of third bonding pads 18 and the plurality of fourth bonding pads 19 are not included is illustrated. FIG. 11 is also a diagram illustrating the inside of three-dimensional stacked device 10 for explaining the electrical connection relation of three-dimensional stacked device 10.

In addition, in FIG. 11, the lines extending from the bonding pads are lines schematically indicating the electrical connection between substrate 11 and semiconductor die 12A and the electrical connection between three semiconductor dies 12, and are not lines indicating accurate line paths.

As illustrated in FIG. 11, when focusing on the connection relation between substrate 11 and semiconductor die 12A, the plurality of second bonding pads 17A included in semiconductor die 12A are electrically connected, via bump 30, to substrate 11.

In addition, focusing on the connection relation between semiconductor die 12A and semiconductor die 12B, the plurality of second bonding pads 17B included in semiconductor die 12B are electrically connected, via bump 30, respectively to the plurality of first bonding pads 16A included in semiconductor die 12A. In other words, semiconductor die 12B is stacked above semiconductor die 12A such that, when viewed in the direction perpendicular to top surface 14 or bottom surface 15, the plurality of second bonding pads 17B included in semiconductor die 12B are electrically connected to the plurality of first bonding pads 16A included in semiconductor die 12A with the positions of the plurality of second bonding pads 17B matching the positions of the plurality of first bonding pads 16A.

In addition, when focusing on the connection relation between semiconductor die 12B and semiconductor die 12C, the plurality of second bonding pads 17C included in semiconductor die 12C are electrically connected, via bump 30, respectively to the plurality of first bonding pads 16B included in semiconductor die 12B. In other words, semiconductor die 12C is stacked above semiconductor die 12B such that, when viewed in the direction perpendicular to top surface 14 or bottom surface 15, the plurality of second bonding pads 17C included in semiconductor die 12C are electrically connected to the plurality of first bonding pads 16B included in semiconductor die 12B with the positions of the plurality of second bonding pads 17C matching the positions of the plurality of first bonding pads 16B.

It should be noted that the same is also true for the case where semiconductor die 12 includes a plurality of third bonding pads 18. For example, semiconductor die 12B may be stacked above semiconductor die 12A such that, when viewed in the direction perpendicular to top surface 14 or bottom surface 15, the plurality of second bonding pads 17B included in semiconductor die 12B are electrically connected to the plurality of third bonding pads 18A included in semiconductor die 12A with the positions of the plurality of second bonding pads 17B matching the positions of the plurality of third bonding pads 18A. The same is also true for the case where a plurality of fourth bonding pads 19 are included.

### [Variation of Three-Dimensional Stacked Device]

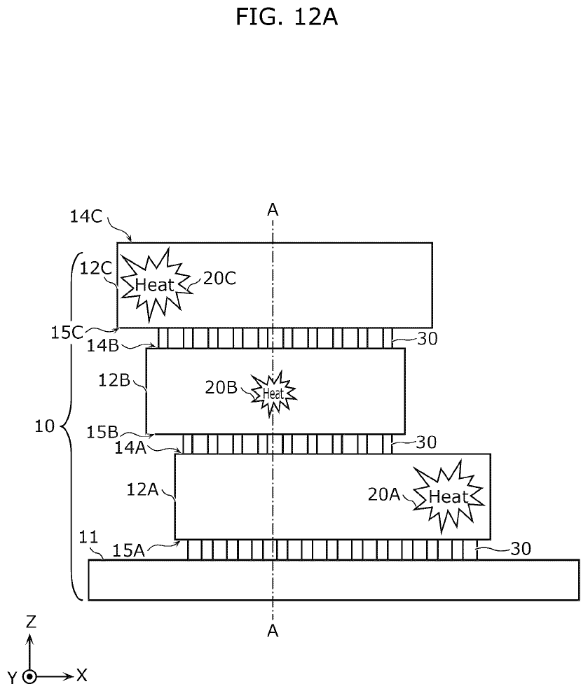

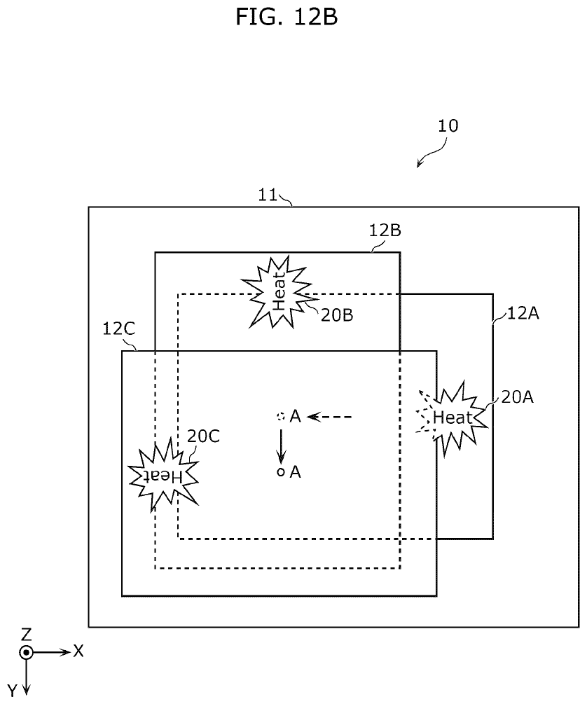

Next, a variation of three-dimensional stacked device 10 according to Embodiment 2 will be described with reference to FIG. 12A and FIG. 12B. FIG. 12A is a schematic diagram illustrating the configuration of three-dimensional stacked device 10 when viewed in a direction parallel to the Y direction. FIG. 12B is a schematic diagram illustrating the configuration of three-dimensional stacked device 10 when viewed in a direction parallel to the Z direction. FIG. 12B is a schematic diagram illustrating three-dimensional stacked device 10 illustrated in FIG. 12A when viewed in a direction parallel to the Z direction.

As illustrated in FIG. 12A and FIG. 12B, when focusing on the positional relationship between semiconductor die 12A and semiconductor die 12B, semiconductor die 12B is shifted parallel in the direction indicated by a dashed arrow (direction parallel to the X direction) with respect to semiconductor die 12A, and then rotationally shifted counterclockwise by 90 degrees about line A-A as a central axis.

In addition, when focusing on the positional relationship between semiconductor die 12B and semiconductor die 12C, semiconductor die 12C is shifted parallel in the direction indicated by an arrow (direction parallel to the Y direction) with respect to semiconductor die 12B, and then rotationally shifted counterclockwise by 90 degrees about line A-A as a central axis.

As described above, since three-dimensional stacked device 10 has the configuration as illustrated in FIG. 12A and FIG. 12B, the positions of heat sources (i.e., heat 20A, heat 20B, and heat 20C) are shifted when viewed in the direction parallel to the Z direction (the stacking direction) as illustrated in FIG. 12B. In this manner, three-dimensional stacked device 10 is capable of reducing the density of the heat sources to be smaller than the density of the heat sources of three-dimensional stacked device 100 according to the comparison example.

It should be noted that, it is possible to implement the electrical connection relation of three-dimensional stacked device 10 illustrated in FIG. 12A and FIG. 12B, by combining the electrical connection relation illustrated in FIG. 4 to FIG. 6B and the electrical connection relation illustrated in FIG. 11.

### Advantageous Effects, Etc

As described above, in semiconductor die 12 according to the present embodiment, the certain way in which the plurality of second bonding pads 17 are shifted in the plane of bottom surface 15 while maintaining the positional relationship between the plurality of second bonding pads 17 is rotational shift about predetermined point T located on bottom surface 15.

According to this configuration, semiconductor die 12 is located at a position where the plurality of first bonding pads 16 do not overlap the plurality of second bonding pads 17 when viewed in a direction perpendicular to top surface 14 or bottom surface 15, and thus when the plurality of semiconductor dies 12 are stacked, the position of the main heat source that generates heat in each semiconductor die 12 can be shifted. As a result, semiconductor die 12 is capable of more efficiently dissipating heat generated inside three-dimensional stacked device 10 (i.e., SoC).

In addition, in semiconductor die 12 according to the present embodiment, when semiconductor die 12 has a quadrilateral shape, predetermined point T may be the intersection point of the diagonal lines of the quadrilateral shape.

According to this configuration, semiconductor die 12 is located at a position where the plurality of first bonding pads 16 do not overlap the plurality of second bonding pads 17 when viewed in a direction perpendicular to top surface 14 or bottom surface 15, and thus when the plurality of semiconductor dies 12 are stacked, the position of the main heat source that generates heat in each semiconductor die 12 can be shifted. As a result, semiconductor die 12 is capable of more efficiently dissipating heat generated inside three-dimensional stacked device 10 (i.e., SoC).

In addition, in semiconductor die 12 according to the present embodiment, the certain way in which the plurality of second bonding pads 17 are shifted in the plane of bottom surface 15 while maintaining the positional relationship between the plurality of second bonding pads 17 is parallel shift in the plane of the bottom surface and rotational shift about predetermined point T located on bottom surface 15.

According to this configuration, semiconductor die 12 is located at a position where the plurality of first bonding pads 16 do not overlap the plurality of second bonding pads 17 when viewed in a direction perpendicular to top surface 14 or bottom surface 15, and thus when the plurality of semiconductor dies 12 are stacked, the position of the main heat source that generates heat in each semiconductor die 12 can be shifted. As a result, semiconductor die 12 is capable of more efficiently dissipating heat generated inside three-dimensional stacked device 10 (i.e., SoC).

In addition, three-dimensional stacked device 10 according to the present embodiment is three-dimensional stacked device 10 having a configuration in which a plurality of semiconductor dies 12 according to the present disclosure are stacked. In three-dimensional stacked device 10, the plurality of semiconductor dies include first semiconductor die 12 and second semiconductor die 12, and when viewed in the direction perpendicular to top surface 14 or bottom surface 15, second semiconductor die 12 is stacked above first semiconductor die 12, with positions of the plurality of second bonding pads 17 included in second semiconductor die 12 matching positions of the plurality of first bonding pads 16 included in first semiconductor die 12.

According to this configuration, the plurality of semiconductor dies 12 are stacked in a state in which the position of the main heat source that generates heat in each semiconductor die 12 is shifted, and thus three-dimensional stacked device 10 is capable of reducing the density of the heat source to be smaller than three-dimensional stacked device 100 of the comparison example. As a result, it is possible for three-dimensional stacked device 10 (i.e., SoC) to more efficiently dissipate heat generated inside.

In addition, in three-dimensional stacked device 10 according to the present embodiment, when viewed in the direction perpendicular to top surface 14 or bottom surface 15, second semiconductor die 12 is stacked above first semiconductor die 12 with a portion of second semiconductor die 12 not overlapping first semiconductor die 12.

According to this configuration, in a region in which the portion of second semiconductor die 12 does not overlap first semiconductor die 12, it is easier to dissipate heat than in a region in which two semiconductor dies overlap, and thus three-dimensional stacked device 10 (i.e., SoC) is capable of more efficiently dissipating heat generated inside.

In addition, three-dimensional stacked device 10 according to the present embodiment is three-dimensional stacked device 10 having a configuration in which a plurality of semiconductor dies 12 according to the present disclosure are stacked. In three-dimensional stacked device 10, the plurality of semiconductor dies include first semiconductor die 12 and second semiconductor die 12, and second semiconductor die 12 is stacked above first semiconductor die 12: with positions of the plurality of second bonding pads 17 included in second semiconductor die 12 matching positions of the plurality of first bonding pads 16 included in first semiconductor die 12, when viewed in the direction perpendicular to top surface 14 or bottom surface 15; or with the positions of the plurality of second bonding pads 17 included in second semiconductor die 12 matching positions of the plurality of third bonding pads 18 included in first semiconductor die 12, when viewed in the direction perpendicular to top surface 14 or bottom surface 15.

According to this configuration, three-dimensional stacked device 10 described here yields advantageous effects equivalent to the advantageous effects of the above-described three-dimensional stacked device 10. In addition, when stacking second semiconductor die 12 above first semiconductor die 12, a user can select as appropriate bonding pads to be connected to the plurality of second bonding pads 17 from among the plurality of first bonding pads 16 and the plurality of third bonding pads 18. As a result, it is possible for a user to change the electrical connection paths of the plurality of semiconductor dies 12 according to the amount of heat generated in each semiconductor die 12.

In addition, three-dimensional stacked device 10 according to the present embodiment is three-dimensional stacked device 10 having a configuration in which a plurality of semiconductor dies 12 according to the present disclosure are stacked. In three-dimensional stacked device 10, the plurality of semiconductor dies include first semiconductor die 12 and second semiconductor die 12, and second semiconductor die 12 is stacked above first semiconductor die 12: with positions of the plurality of second bonding pads 17 included in second semiconductor die 12 matching positions of the plurality of first bonding pads 16 included in first semiconductor die 12, when viewed in the direction perpendicular to top surface 14 or bottom surface 15; or with positions of the plurality of fourth bonding pads 19 included in second semiconductor die 12 matching the positions of the plurality of first bonding pads 16 included in first semiconductor die 12, when viewed in the direction perpendicular to top surface 14 or bottom surface 15.

According to this configuration, three-dimensional stacked device 10 described here yields advantageous effects equivalent to the advantageous effects of the above-described three-dimensional stacked device 10. In addition, when stacking second semiconductor die 12 above first semiconductor die 12, a user can select as appropriate bonding pads to be connected to the plurality of first bonding pads 16 from among the plurality of second bonding pads 17 and the plurality of fourth bonding pads 19. As a result, it is possible for a user to change the electrical connection paths of the plurality of semiconductor dies 12 according to the amount of heat generated in each semiconductor die 12.

### Other Variations

Although the semiconductor die and three-dimensional stacked device according to the present disclosure have been described based on the embodiments, the present disclosure is not limited to the above embodiments.

Those skilled in the art will readily appreciate that various modifications may be made in the embodiments and the variations of the embodiments described above, and that other embodiments may be obtained by arbitrarily combining the structural components and functions of the embodiment and the variation of the embodiment without materially departing from the novel teachings and advantages of the present disclosure. Accordingly, all such modifications and other embodiments are included in the present disclosure.

For example, the case where first bonding pad 16 and third bonding pad 18 on the top surface of semiconductor die 12 and second bonding pad 17 and plurality of fourth bonding pads 19 on the bottom surface of semiconductor die 12, which are explained as bonding pads in one set, are directly and electrically connected inside semiconductor die 12 (in other words, bonding pads in one set are connected to one another only via lines) has been described, through Embodiments 1 and 2, but the same advantageous effects are yielded even without this feature.

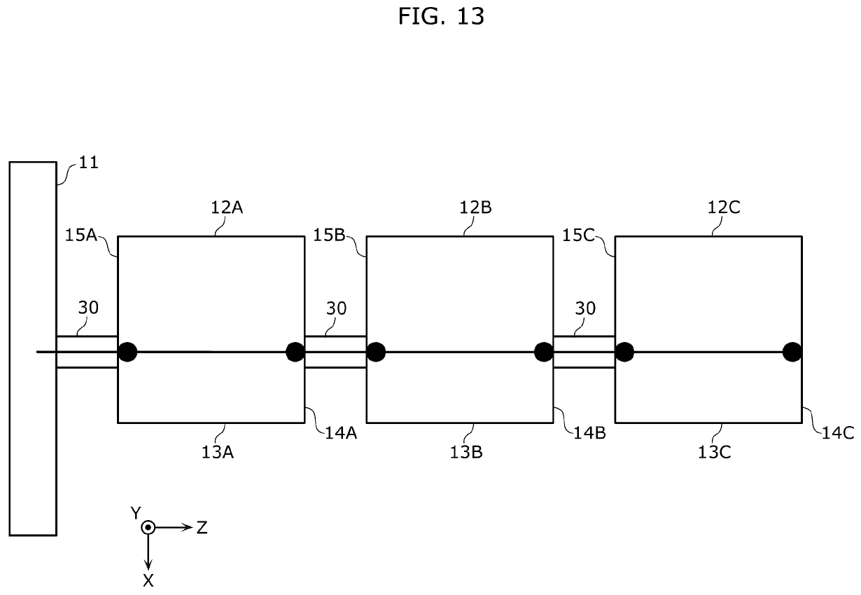

The following describes two specific examples to illustrate the case where bonding pads in one set (first bonding pad 16, second bonding pad 17, third bonding pad 18, and fourth bonding pad 19) are connected to one another without direct electrical connection inside semiconductor die 12. When bonding pads in one set are connected to one another without direct electrical connection inside semiconductor die 12, it means that the bonding pads in one set are connected to one another via some sort of circuit or the like inside semiconductor die 12. It should be noted that, in regard to FIG. 13 to FIG. 16B to be referred to in the description below, only a single bonding pad (indicated as a filled circle in the diagram) is illustrated for each of top surface 14 and bottom surface 15 of semiconductor die 12 in order to make the schematic diagrams less complicated. In addition, in FIG. 13 to FIG. 16B, a simplified state of the cross-section of semiconductor die 12 are illustrated ignoring vertical and horizontal scaling. Furthermore, FIG. 13 to FIG. 16B illustrate the stacking direction of semiconductor dies 12 in a horizontal orientation.

FIG. 13 is a schematic diagram illustrating how bonding pads in one set are directly and electrically connected to one another inside semiconductor die 12. It should be noted that, in FIG. 13, the solid lines connecting the bonding pads are lines indicating that the bonding pads are directly and electrically connected.

As illustrated in FIG. 13, the bonding pads disposed on top surface 14A and bottom surface 15A of semiconductor die 12A are directly and electrically connected inside main body 13A. The same is true for semiconductor dies 12B and 12C. In other words, the schematic diagram illustrated in FIG. 13 corresponds to the case where bonding pads in one set are directly and electrically connected to one another inside semiconductor die 12 (the above-described Embodiments 1 and 2).

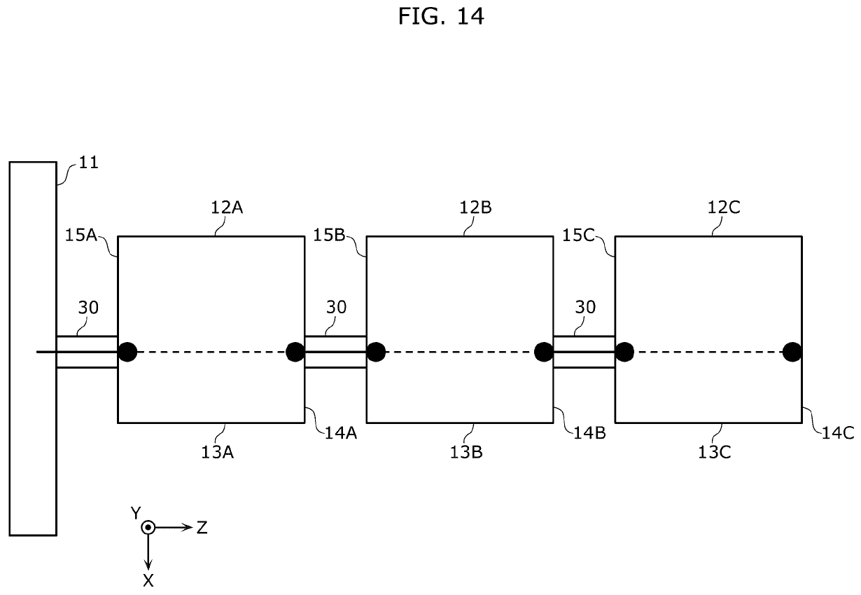

FIG. 14 is a schematic diagram illustrating how bonding pads in one set are connected to one another without direct electrical connection inside semiconductor die 12. It should be noted that, in FIG. 14, the solid lines connecting the bonding pads are lines indicating that the bonding pads are directly and electrically connected, and the dashed lines connecting the bonding pads are lines indicating that the bonding pads are connected to one another without direct electrical connection.

As illustrated in FIG. 14, the bonding pads disposed on top surface 14A and bottom surface 15A of semiconductor die 12A are connected without direct electrical connection inside main body 13A. The same is true for semiconductor dies 12B and 12C.

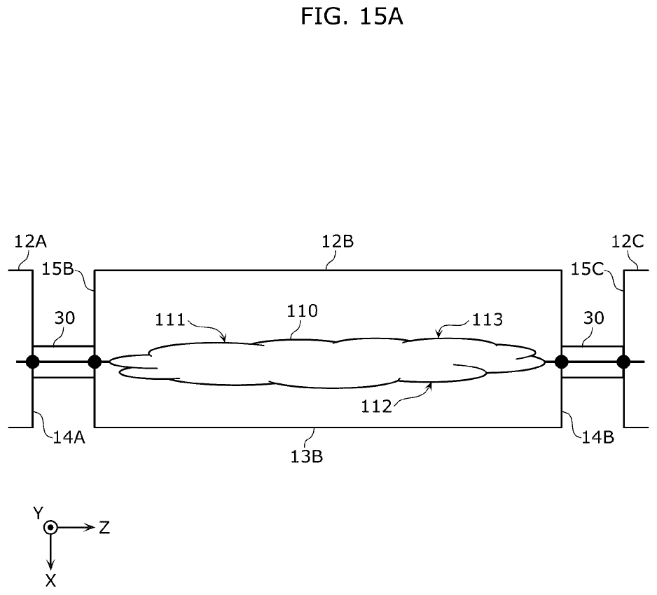

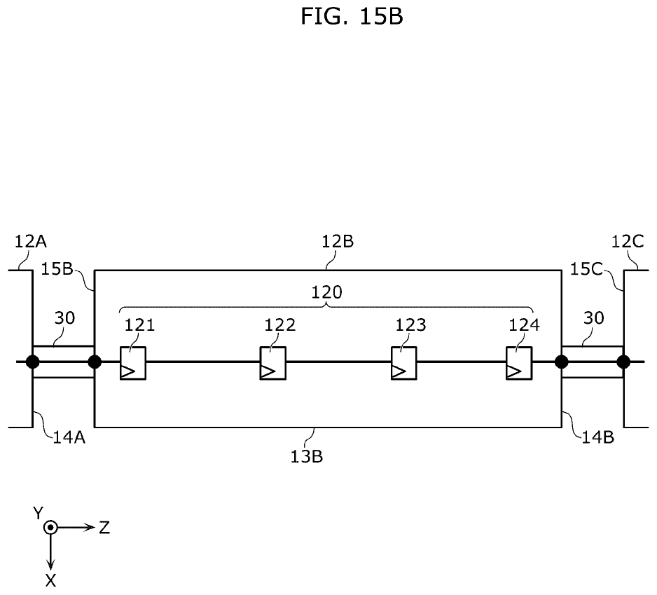

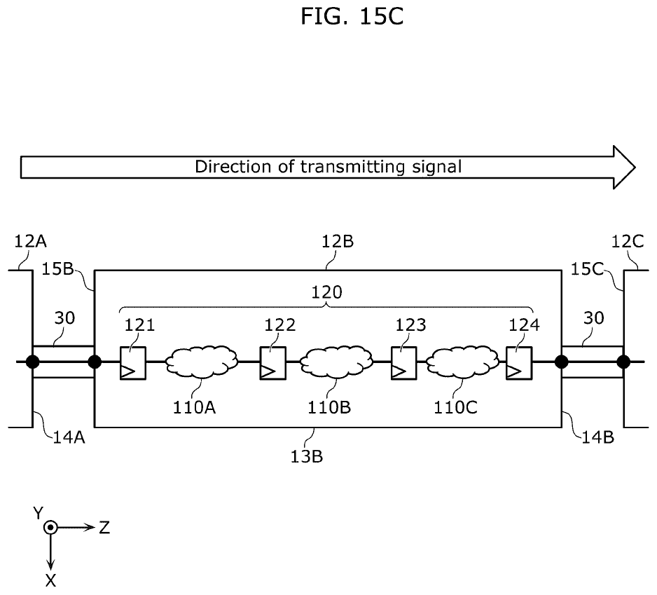

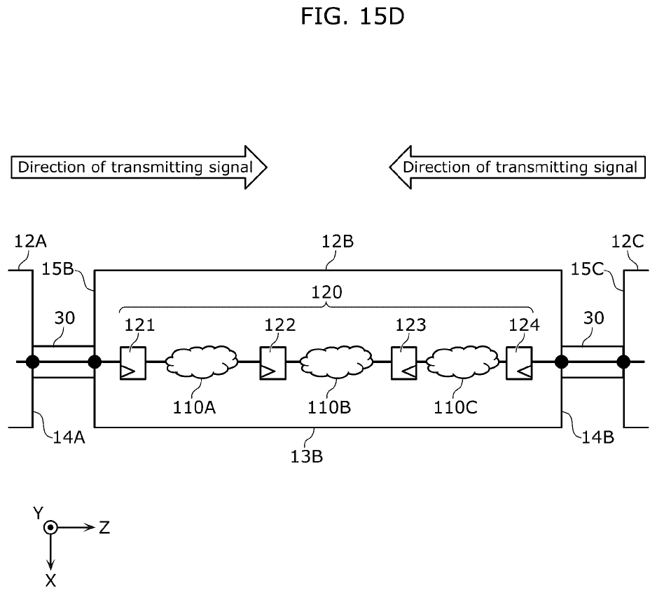

First, the first specific example of the case where bonding pads in one set are connected to one another without direct electrical connection inside semiconductor die 12. The first specific example is the case where bonding pads in one set (first bonding pad 16, second bonding pad 17, third bonding pad 18, and fourth bonding pad 19) are electrically connected to one another via an element such as a transistor. The following describes the first specific example with reference to FIG. 15A to FIG. 15D. FIG. 15A to FIG. 15D illustrate enlarged views focusing on semiconductor die 12B among semiconductor dies 12A, 12B, and 12C illustrated in FIG. 14.

FIG. 15A is a schematic diagram illustrating the case where main body 13B of semiconductor die 12B includes first logic circuit 110 inside. In this Specification, first logic circuit 110 includes, for example, one or more combinational circuits. The combinational circuits are each a circuit group (including the case where only one circuit is provided) with no temporal difference between an input signal and an output signal.

As illustrated in FIG. 15A, main body 13B includes first logic circuit 110 (corresponding, for example, to one internal circuit among one or more internal circuits) disposed between top surface 14B and bottom surface 15B. The bonding pad disposed on top surface 14B of semiconductor die 12B and the bonding pad disposed on bottom surface 15B of semiconductor die 12B are electrically connected to first logic circuit 110. It should be noted that first logic circuit 110 may perform logical operation by being applied with some sort of signals 111, 112, and 113, for example, inside main body 13B.

In addition, the signal passing through the bonding pad disposed on top surface 14B may be an input signal provided to semiconductor 12B, or may be an output signal output through semiconductor 12B. The same is true for the signal passing through the bonding pad disposed on bottom surface 15B.

In addition, for example, when signals are transmitted in order of semiconductor die 12A, 12B, and 12C, each semiconductor die 12 may output, to the next semiconductor die 12, a signal resulting from internally processing the input signal. In addition, for example, when signals are transmitted in order from semiconductor die 12A to semiconductor die 12B and from semiconductor die 12B to semiconductor die 12C, each semiconductor die 12 may output a signal generated in semiconductor die 12 to the next semiconductor die 12, irrespective of the input signal.

In addition, a signal may be input from the bonding pad disposed on top surface 14B to semiconductor die 12B and output from semiconductor die 12B to the bonding pad disposed on bottom surface 15B, or vice versa.

FIG. 15B is a schematic diagram illustrating the case where main body 13B of semiconductor die 12B includes second logic circuit 120 inside. In this Specification, second logic circuit 120 includes one or more sequential circuits (sequential circuits 121, 122, 123, and 124 in the example illustrated in FIG. 15B). The sequential circuits are each a circuit group (including the case where only one circuit is provided) with a temporal difference between an input signal and an output signal, rather than a temporal difference due to signal propagation delay.

As illustrated in FIG. 15B, main body 13B includes second logic circuit 120 (corresponding, for example, to one internal circuit among one or more internal circuits) disposed between top surface 14B and bottom surface 15B. The bonding pad disposed on top surface 14B of semiconductor die 12B and the bonding pad disposed on bottom surface 15B of semiconductor die 12B are electrically connected to second logic circuit 120. The example illustrated in FIG. 15B is in shift register format in which signals are transmitted from bottom surface 15B to top surface 14B. Typical applications of the shift register format include, for example, the case of forming a scan chain.

It should be noted that, in the example illustrated in FIG. 15B, the case where a signal is transmitted from bottom surface 15B to top surface 14B has been indicated, but the signal may be transmitted from top surface 14B to bottom surface 15B.

In addition, as illustrated in FIG. 15C, first logic circuits 110A, 110B, and 110C may be disposed in second logic circuit 120. FIG. 15C is a schematic diagram illustrating the case where main body 13B of semiconductor die 12B includes first logic circuits 110A, 110B, and 110C, and second logic circuit 120 inside. In the example illustrated in FIG. 15C, the case where a signal is transmitted from bottom surface 15B to top surface 14B (in the direction indicated by arrows in FIG. 15C) has been indicated, but the signal may be transmitted from top surface 14B to bottom surface 15B. It should be noted that an additional character of “A”, “B”, or “C” is added to the numerical references of first logic circuit 110A, 110B, and 110C for making the description easier to understand. Accordingly, each of first logic circuits 110A, 110B, and 110C has a similar configuration to that of first logic circuit 110. In general, a combinational circuit and a sequential circuit may be included as logic circuits.

The direction of transmitting a signal does not necessarily have to be in one direction. FIG. 15D is a schematic diagram illustrating the case where signals are transmitted in two directions, from top surface 14B and from bottom surface 15B. As illustrated in FIG. 15D, signals may be transmitted (input) from the bonding pad disposed on top surface 14B to semiconductor die 12B, and from the bonding pad disposed on bottom surface 15B to semiconductor die 12B. Conversely, signals may be transmitted (output) from semiconductor die 12B to the bonding pad disposed on top surface 14B, and from semiconductor die 12B to bonding pad disposed on bottom surface 15B (not illustrated).

In addition, the clock signal input to second logic circuit 120 may be a clock signal generated inside semiconductor die 12B, or may be a clock signal input from outside semiconductor die 12B.

The clock signals input to second logic circuit 120 included in each of semiconductor dies 12A, 12B, and 12C may be synchronized or may not be synchronized. However, in the case of a shift register format as in the example illustrated in FIG. 15B, the clock signals may be synchronized.

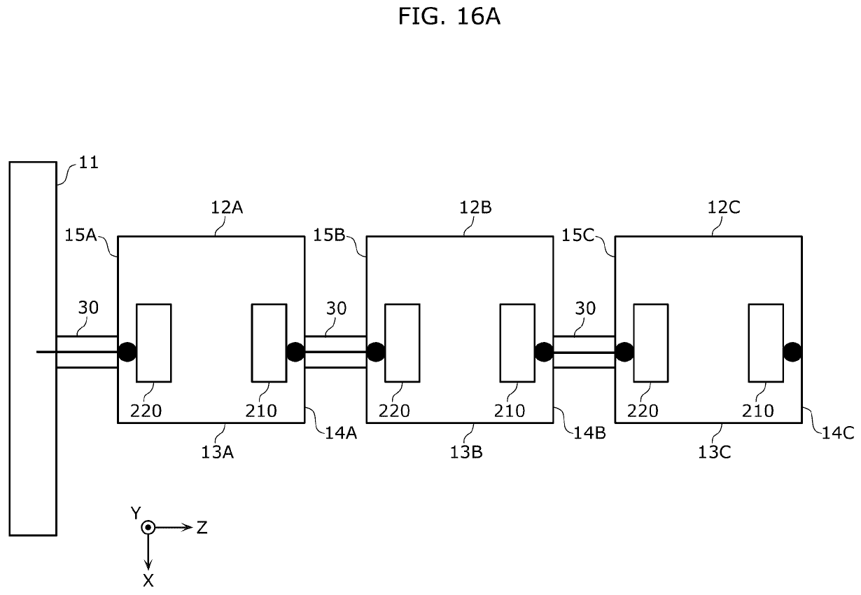

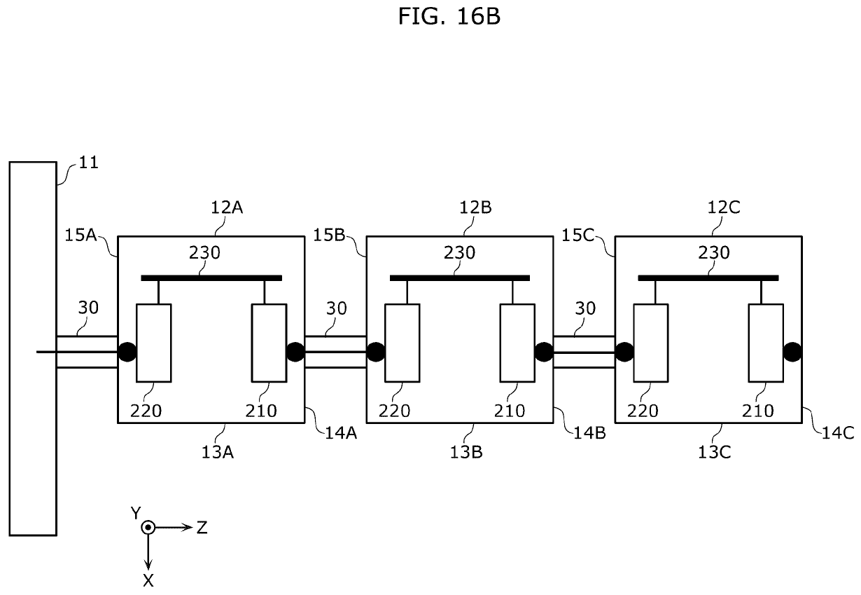

Next, the second specific example of the case where bonding pads in one set are connected to one another without direct electrical connection inside semiconductor die 12. The second specific example is the case where second bonding pad 17 and fourth bonding pad 19 on bottom surface 15 of semiconductor die 12 stacked above are simply connected to first bonding pad 16 and third bonding pad 18 on top surface 14 of semiconductor die 12 stacked below. Here, “simply” means that other elements such as a transistor are not involved in the connection. The following describes the second specific example with reference to FIG. 16A and FIG. 16B.

FIG. 16A is a schematic diagram illustrating the case where main body 13 of semiconductor die 12 includes two interface circuits 210 and 220 inside.

As illustrated in FIG. 16A, main body 13B of semiconductor die 12B includes interface circuit 210 (corresponds to first inter-die interface circuit) that exchanges signals with semiconductor die 12C. In addition, main body 13B includes interface circuit 220 (corresponds to second inter-die interface circuit) that exchanges signals with semiconductor die 12A and is different from interface circuit 210. The bonding pad disposed on top surface 14B of semiconductor die 12B is connected to interface circuit 210, and the bonding pad disposed on bottom surface 15B of semiconductor die 12B is connected to interface circuit 220. The same is true for semiconductor dies 12A and 12C. The two interface circuits 210 and 220 may support, for example, universal chiplet inretconnect express (UCIe). Furthermore, each of the two interface circuits 210 and 220 may operate independently of each other. The two interface circuits 210 and 220 are each, for example, an input/output circuit that exchanges signals with the outside, and includes, for example, various transistors, etc.

FIG. 16B is a schematic diagram illustrating the case where the two interface circuits 210 and 220 that main body 13 of semiconductor die 12 includes inside are electrically connected to each other.

As illustrated in FIG. 16B, the two interface circuits 210 and 220 that main body 13A of semiconductor die 12A includes inside may be electrically connected to each other via bus 230, for example. It should be noted that, in such a case as well, each of the two interface circuits 210 and 220 may operate independently of each other. The same is true for semiconductor dies 12B and 12C.

Typical configurations when two interface circuits 210 and 220 are electrically connected to each other as in the example illustrated in FIG. 16B may include a configuration in which a processor (not illustrated) that corresponds to a controller in semiconductor die 12 updates a control register of each of the two interface circuits 210 and 220 via bus 230, thereby controlling each of the two interface circuits 210 and 220.

In addition, the two interface circuits 210 and 220 may be electrically connected to the above-described one or more internal circuits (e.g., first logic circuit 110 or second logic circuit 120).

The following describes examples of the semiconductor die and the three-dimensional stacked device according to the present disclosure that have been described based on the foregoing embodiments. The semiconductor die and the three-dimensional stacked device according to the present disclosure are not limited to the examples described below.

For example, a semiconductor die according to the first aspect of the present disclosure is a semiconductor die that is used in a three-dimensional stacked device including a plurality of semiconductor dies which are same in configuration and stacked on one another, the plurality of semiconductor dies each being the semiconductor die. The semiconductor die includes: a main body including a top surface and a bottom surface; a plurality of first bonding pads disposed on the top surface; and a plurality of second bonding pads disposed on the bottom surface. In the semiconductor die, the top surface is one of principal surfaces of the main body, the bottom surface is a surface opposing the top surface, when viewed in a direction perpendicular to the top surface or the bottom surface, the plurality of first bonding pads are disposed at positions that match positions to which the plurality of second bonding pads are shifted in a certain way in a plane of the bottom surface while maintaining a positional relationship between the plurality of second bonding pads, the main body includes a first inter-die interface circuit and a second inter-die interface circuit which are disposed between the top surface and the bottom surface, the second inter-die interface circuit being different from the first inter-die interface circuit, the plurality of first bonding pads are connected to the first inter-die interface circuit, and the plurality of second bonding pads are connected to the second inter-die interface circuit.

In addition, for example, a semiconductor die according to the second aspect of the present disclosure is the semiconductor die according to the first aspect, and in the semiconductor die according to the second aspect, the main body includes one or more internal circuits disposed between the top surface and the bottom surface, the one or more internal circuits are each a combinational circuit or a sequential circuit, the first inter-die interface circuit is connected to the one or more internal circuits, and the second inter-die interface circuit is connected to the one or more internal circuits.

In addition, for example, a semiconductor die according to the third aspect of the present disclosure is the semiconductor die according to the second aspect, and in the semiconductor die according to the third aspect, the main body includes a plurality of sequential circuits each being the sequential circuit, and the plurality of sequential circuits are provided with a same clock signal.

In addition, for example, a semiconductor die according to the fourth aspect of the present disclosure is the semiconductor die according to any one of the first aspect to the third aspect, and in the semiconductor die according to the fourth aspect, the first inter-die interface circuit and the second inter-die interface circuit operate independently of each other.

In addition, for example, a semiconductor die according to the fifth aspect of the present disclosure is the semiconductor die according to any one of the first aspect to the fourth aspect, and in the semiconductor die according to the fifth aspect, the certain way in which the plurality of second bonding pads are shifted is (i) parallel shift in the plane of the bottom surface, (ii) rotational shift about a predetermined point located on the bottom surface, or (iii) the parallel shift in the plane of the bottom surface and the rotational shift about the predetermined point located on the bottom surface.

In addition, for example, a semiconductor die according to the sixth aspect of the present disclosure is the semiconductor die according to any one of the first aspect to the fifth aspect, and the semiconductor die according to the sixth aspect further includes a plurality of third bonding pads disposed on the top surface of the main body. In the semiconductor die according to the sixth aspect, when viewed in the direction perpendicular to the top surface or the bottom surface, the plurality of third bonding pads are disposed at positions that match positions to which the plurality of second bonding pads are shifted in the certain way in the plane of the bottom surface while maintaining the positional relationship between the plurality of second bonding pads, and the plurality of third bonding pads are electrically connected one to one to the plurality of first bonding pads disposed on the main body where the plurality of third bonding pads are disposed.

In addition, for example, a semiconductor die according to the seventh aspect of the present disclosure is the semiconductor die according to any one of the first aspect to the sixth aspect, and the semiconductor die according to the seventh aspect further includes a plurality of fourth bonding pads disposed on the bottom surface of the main body. In the semiconductor die according to the seventh aspect, when viewed in the direction perpendicular to the top surface or the bottom surface, the plurality of first bonding pads are disposed at positions that match positions to which the plurality of fourth bonding pads are shifted in the certain way in the plane of the bottom surface while maintaining a positional relationship between the plurality of fourth bonding pads, and the plurality of fourth bonding pads are electrically connected one to one to the plurality of second bonding pads disposed on the main body where the plurality of fourth bonding pads are disposed.

In addition, for example, a three-dimensional stacked device according to the eighth aspect of the present disclosure is the three-dimensional stacked device in which a plurality of semiconductor dies each being the semiconductor die according to any one of the first aspect to the seventh aspect are stacked, and in the three-dimensional stacked device according to the eighth aspect, the plurality of semiconductor dies include a first semiconductor die and a second semiconductor die, and when viewed in the direction perpendicular to the top surface or the bottom surface, the second semiconductor die is stacked above the first semiconductor die, with positions of the plurality of second bonding pads included in the second semiconductor die matching positions of the plurality of first bonding pads included in the first semiconductor die.

In addition, for example, a three-dimensional stacked device according to the ninth aspect of the present disclosure is the three-dimensional stacked device according to the eighth aspect, and in the three-dimensional stacked device according to the ninth aspect, when viewed in the direction perpendicular to the top surface or the bottom surface, the second semiconductor die is stacked above the first semiconductor die with a portion of the second semiconductor die not overlapping the first semiconductor die.

In addition, for example, a three-dimensional stacked device according to the tenth aspect of the present disclosure is the three-dimensional stacked device in which a plurality of semiconductor dies each being the semiconductor die according to the sixth aspect are stacked, and in the three-dimensional stacked device according to the tenth aspect, the plurality of semiconductor dies include a first semiconductor die and a second semiconductor die, and the second semiconductor die is stacked above the first semiconductor die: with positions of the plurality of second bonding pads included in the second semiconductor die matching positions of the plurality of first bonding pads included in the first semiconductor die, when viewed in the direction perpendicular to the top surface or the bottom surface; or with the positions of the plurality of second bonding pads included in the second semiconductor die matching positions of the plurality of third bonding pads included in the first semiconductor die, when viewed in the direction perpendicular to the top surface or the bottom surface.

In addition, for example, a three-dimensional stacked device according to the eleventh aspect of the present disclosure is the three-dimensional stacked device in which a plurality of semiconductor dies each being the semiconductor die according to the seventh aspect are stacked, and in the three-dimensional stacked device according to the eleventh aspect, the plurality of semiconductor dies include a first semiconductor die and a second semiconductor die, and the second semiconductor die is stacked above the first semiconductor die: with positions of the plurality of second bonding pads included in the second semiconductor die matching positions of the plurality of first bonding pads included in the first semiconductor die, when viewed in the direction perpendicular to the top surface or the bottom surface; or with positions of the plurality of fourth bonding pads included in the second semiconductor die matching the positions of the plurality of first bonding pads included in the first semiconductor die, when viewed in the direction perpendicular to the top surface or the bottom.

In addition, for example, a three-dimensional stacked device according to the twelfth aspect of the present disclosure is the three-dimensional stacked device according to the tenth aspect, and in the three-dimensional stacked device according to the twelfth aspect, when viewed in the direction perpendicular to the top surface or the bottom surface, the second semiconductor die is stacked above the first semiconductor die with a portion of the second semiconductor die not overlapping the first semiconductor die.

In addition, for example, a three-dimensional stacked device according to the thirteenth aspect of the present disclosure is the three-dimensional stacked device according to the eleventh aspect, and in the three-dimensional stacked device according to the thirteenth aspect, when viewed in the direction perpendicular to the top surface or the bottom surface, the second semiconductor die is stacked above the first semiconductor die with a portion of the second semiconductor die not overlapping the first semiconductor die.

### INDUSTRIAL APPLICABILITY

The semiconductor die, etc. according to the present disclosure are applicable to various electrical devices that use a semiconductor chip.

1. A semiconductor die that is used in a three-dimensional stacked device including a plurality of semiconductor dies which are same in configuration and stacked on one another, the plurality of semiconductor dies each being the semiconductor die, the semiconductor die comprising:
a main body including a top surface and a bottom surface;
a plurality of first bonding pads disposed on the top surface; and
a plurality of second bonding pads disposed on the bottom surface, wherein
the top surface is one of principal surfaces of the main body,
the bottom surface is a surface opposing the top surface,
when viewed in a direction perpendicular to the top surface or the bottom surface, the plurality of first bonding pads are disposed at positions that match positions to which the plurality of second bonding pads are shifted in a certain way in a plane of the bottom surface while maintaining a positional relationship between the plurality of second bonding pads,
the main body includes a first inter-die interface circuit and a second inter-die interface circuit which are disposed between the top surface and the bottom surface, the second inter-die interface circuit being different from the first inter-die interface circuit,
the plurality of first bonding pads are connected to the first inter-die interface circuit, and
the plurality of second bonding pads are connected to the second inter-die interface circuit.

2. The semiconductor die according to claim 1, wherein
the main body includes one or more internal circuits disposed between the top surface and the bottom surface,
the one or more internal circuits are each a combinational circuit or a sequential circuit,
the first inter-die interface circuit is connected to the one or more internal circuits, and
the second inter-die interface circuit is connected to the one or more internal circuits.

3. The semiconductor die according to claim 2, wherein
the main body includes a plurality of sequential circuits each being the sequential circuit, and
the plurality of sequential circuits are provided with a same clock signal.

4. The semiconductor die according to claim 1, wherein
the first inter-die interface circuit and the second inter-die interface circuit operate independently of each other.

5. The semiconductor die according to claim 1, wherein
the certain way in which the plurality of second bonding pads are shifted is
(i) parallel shift in the plane of the bottom surface,
(ii) rotational shift about a predetermined point located on the bottom surface, or
(iii) the parallel shift in the plane of the bottom surface and the rotational shift about the predetermined point located on the bottom surface.

6. The semiconductor die according to claim 2, further comprising:
a plurality of third bonding pads disposed on the top surface of the main body, wherein
when viewed in the direction perpendicular to the top surface or the bottom surface, the plurality of third bonding pads are disposed at positions that match positions to which the plurality of second bonding pads are shifted in the certain way in the plane of the bottom surface while maintaining the positional relationship between the plurality of second bonding pads, and
the plurality of third bonding pads are electrically connected one to one to the plurality of first bonding pads disposed on the main body where the plurality of third bonding pads are disposed.

7. The semiconductor die according to claim 3, further comprising:
a plurality of third bonding pads disposed on the top surface of the main body, wherein
when viewed in the direction perpendicular to the top surface or the bottom surface, the plurality of third bonding pads are disposed at positions that match positions to which the plurality of second bonding pads are shifted in the certain way in the plane of the bottom surface while maintaining the positional relationship between the plurality of second bonding pads, and
the plurality of third bonding pads are electrically connected one to one to the plurality of first bonding pads disposed on the main body where the plurality of third bonding pads are disposed.

8. The semiconductor die according to claim 2, further comprising:
a plurality of fourth bonding pads disposed on the bottom surface of the main body, wherein
when viewed in the direction perpendicular to the top surface or the bottom surface, the plurality of first bonding pads are disposed at positions that match positions to which the plurality of fourth bonding pads are shifted in the certain way in the plane of the bottom surface while maintaining a positional relationship between the plurality of fourth bonding pads, and
the plurality of fourth bonding pads are electrically connected one to one to the plurality of second bonding pads disposed on the main body where the plurality of fourth bonding pads are disposed.

9. The semiconductor die according to claim 3, further comprising:
a plurality of fourth bonding pads disposed on the bottom surface of the main body, wherein
when viewed in the direction perpendicular to the top surface or the bottom surface, the plurality of first bonding pads are disposed at positions that match positions to which the plurality of fourth bonding pads are shifted in the certain way in the plane of the bottom surface while maintaining a positional relationship between the plurality of fourth bonding pads, and
the plurality of fourth bonding pads are electrically connected one to one to the plurality of second bonding pads disposed on the main body where the plurality of fourth bonding pads are disposed.

10. A three-dimensional stacked device in which the plurality of semiconductor dies according to claim 1 are stacked, wherein
the plurality of semiconductor dies include a first semiconductor die and a second semiconductor die, and
when viewed in the direction perpendicular to the top surface or the bottom surface, the second semiconductor die is stacked above the first semiconductor die, with positions of the plurality of second bonding pads included in the second semiconductor die matching positions of the plurality of first bonding pads included in the first semiconductor die.

11. A three-dimensional stacked device in which the plurality of semiconductor dies according to claim 2 are stacked, wherein
the plurality of semiconductor dies include a first semiconductor die and a second semiconductor die, and
when viewed in the direction perpendicular to the top surface or the bottom surface, the second semiconductor die is stacked above the first semiconductor die, with positions of the plurality of second bonding pads included in the second semiconductor die matching positions of the plurality of first bonding pads included in the first semiconductor die.

12. A three-dimensional stacked device in which the plurality of semiconductor dies according to claim 3 are stacked, wherein
the plurality of semiconductor dies include a first semiconductor die and a second semiconductor die, and
when viewed in the direction perpendicular to the top surface or the bottom surface, the second semiconductor die is stacked above the first semiconductor die, with positions of the plurality of second bonding pads included in the second semiconductor die matching positions of the plurality of first bonding pads included in the first semiconductor die.

13. A three-dimensional stacked device in which the plurality of semiconductor dies according to claim 4 are stacked, wherein
the plurality of semiconductor dies include a first semiconductor die and a second semiconductor die, and
when viewed in the direction perpendicular to the top surface or the bottom surface, the second semiconductor die is stacked above the first semiconductor die, with positions of the plurality of second bonding pads included in the second semiconductor die matching positions of the plurality of first bonding pads included in the first semiconductor die.

14. A three-dimensional stacked device in which the plurality of semiconductor dies according to claim 5 are stacked, wherein
the plurality of semiconductor dies include a first semiconductor die and a second semiconductor die, and
when viewed in the direction perpendicular to the top surface or the bottom surface, the second semiconductor die is stacked above the first semiconductor die, with positions of the plurality of second bonding pads included in the second semiconductor die matching positions of the plurality of first bonding pads included in the first semiconductor die.

15. The three-dimensional stacked device according to claim 14, wherein
when viewed in the direction perpendicular to the top surface or the bottom surface, the second semiconductor die is stacked above the first semiconductor die with a portion of the second semiconductor die not overlapping the first semiconductor die.

16. A three-dimensional stacked device in which the plurality of semiconductor dies according to claim 6 are stacked, wherein
the plurality of semiconductor dies include a first semiconductor die and a second semiconductor die, and
the second semiconductor die is stacked above the first semiconductor die:
with positions of the plurality of second bonding pads included in the second semiconductor die matching positions of the plurality of first bonding pads included in the first semiconductor die, when viewed in the direction perpendicular to the top surface or the bottom surface; or
with the positions of the plurality of second bonding pads included in the second semiconductor die matching positions of the plurality of third bonding pads included in the first semiconductor die, when viewed in the direction perpendicular to the top surface or the bottom surface.

17. A three-dimensional stacked device in which the plurality of semiconductor dies according to claim 8 are stacked, wherein
the plurality of semiconductor dies include a first semiconductor die and a second semiconductor die, and
the second semiconductor die is stacked above the first semiconductor die:
with positions of the plurality of second bonding pads included in the second semiconductor die matching positions of the plurality of first bonding pads included in the first semiconductor die, when viewed in the direction perpendicular to the top surface or the bottom surface; or
with positions of the plurality of fourth bonding pads included in the second semiconductor die matching the positions of the plurality of first bonding pads included in the first semiconductor die, when viewed in the direction perpendicular to the top surface or the bottom surface.

18. The three-dimensional stacked device according to claim 16, wherein
when viewed in the direction perpendicular to the top surface or the bottom surface, the second semiconductor die is stacked above the first semiconductor die with a portion of the second semiconductor die not overlapping the first semiconductor die.

19. The three-dimensional stacked device according to claim 17, wherein
when viewed in the direction perpendicular to the top surface or the bottom surface, the second semiconductor die is stacked above the first semiconductor die with a portion of the second semiconductor die not overlapping the first semiconductor die.
